(19) United States
(12) Patent Application Publication
(10) Pub. No.: US 2024/0162377 A1
(43) Pub. Date: May 16, 2024

(54) SUBSTRATE FOR SEMICONDUCTOR DEVICE, SEMICONDUCTOR COMPONENT AND METHOD OF MANUFACTURING SAME

(71) Applicant: THE ROYAL INSTITUTION FOR THE ADVANCEMENT OF LEARNING/MCGILL UNIVERSITY, Montréal (CA)

(72) Inventors: Songrui ZHAO, Brossard (CA); Qihua ZHANG, Montreal (CA)

(21) Appl. No.: 18/550,708

(22) PCT Filed: Mar. 17, 2022
(86) PCT No.: PCT/CA22/50403

§ 371 Date: Sep. 15, 2023

Related U.S. Application Data
(60) Provisional application No. 63/162,111, filed on Mar. 17, 2021.

(51) Int. Cl. H01L 33/12; H01L 33/00; H01L 33/32; H01L 33/40

(52) U.S. Cl. CPC H01L 33/12; H01L 33/007; H01L 33/32; H01L 33/40

(57) ABSTRACT

There is described a substrate for a semiconductor device. The substrate generally has a semiconductor wafer; an intermediate nanowire layer having a plurality of nanowires each having in succession a base portion mounted to the semiconductor wafer, an elongated body portion extending away from the semiconductor wafer, and a tip portion; and a buffer layer of aluminum nitride being made integral to the tip portions of the plurality of nanowires.

### FIELD

The improvements generally relate to the field of substrates for semiconductor devices, and more particularly relate to group-III nitride-based electronic devices.

### BACKGROUND

In electronics, a substrate generally consists of a thin wafer of semiconductor material on which electronic components are built using one or more microfabrication steps, such as doping, ion implantation, etching, thin-film deposition of various materials, and photolithographic patterning, to name a few exemplary steps. As all these microfabrication steps are performed with great care, the quality of the resulting electronic device typically depends not only on the care with which these steps are performed, but also on the quality of the surface of the substrate on which the electronic components are built upon. As existing manufacturing processes exist to produce silicon-based substrates of satisfactory surface quality, there remain rooms for improvement, especially for group-III nitride-based substrates.

### SUMMARY

It was found that silicon-based substrates having a buffer layer of aluminum nitride (AlN) can be an appealing platform for semiconductor electronic and optoelectronic devices. As high crystalline quality silicon substrates are available at a low cost and the dominant role of silicon on modern semiconductor device technologies, the physical properties of aluminum nitride allows for a wide range of applications including deep ultraviolet (UV) light emitting devices, high electron mobility transistors (HEMTs), microelectromechanical systems (MEMS), surface acoustic wave (SAW) devices and the like. For instance, in deep UV light-emitting devices applications involving aluminum nitride on silicon-based substrates, it was found that there is a direct correlation between the light-emitting device's performance and the quality of the buffer layer of aluminum nitride. There is thus a need in the industry for semiconductor device substrates having a buffer layer of aluminum nitride (AlN) of satisfactory quality. For instance, in some embodiments, the buffer layer is assumed to be of sound quality when an exposed surface thereof has a defect density lower than a given defect density threshold. The low defect density of the buffer layer of aluminum nitride allows for the deposition of electronic components directly atop the buffer layer or indirectly via one or more epilayer(s) of other group-III nitride semiconductor materials.

In accordance with a first aspect of the present disclosure, there is provided a substrate for a semiconductor device, the substrate comprising: a semiconductor wafer; an intermediate nanowire layer having a plurality of nanowires each having in succession a base portion mounted to the semiconductor wafer, an elongated body portion extending away from the semiconductor wafer, and a tip portion; and a buffer layer of aluminum nitride being made integral to the tip portions of the plurality of nanowires.

In accordance with a second aspect of the present disclosure, there is provided a method of manufacturing a substrate for a semiconductor device, the method comprising: growing a plurality of nanowires on a semiconductor wafer, the nanowires having in succession a base portion mounted to the semiconductor wafer, an elongated body portion extending away from the semiconductor wafer, and a tip portion; and making a buffer layer of aluminum nitride integral to the tip portions of the plurality of nanowires.

In accordance with a third aspect of the present disclosure, there is provided a semiconductor device comprising: a semiconductor wafer; an intermediate nanowire layer having a plurality of nanowires each having in succession a base portion mounted to the semiconductor wafer, an elongated body portion extending away from the semiconductor wafer, and a tip portion; a buffer layer of aluminum nitride being made integral to the tip portions of the plurality of nanowires; and a semiconductor component directly or indirectly made integral to the buffer layer of aluminum nitride.

In accordance with a fourth aspect of the present disclosure, there is provided a substrate for a semiconductor device, the substrate comprising: a semiconductor wafer; an intermediate nanowire layer having a plurality of nanowires each having in succession a base portion mounted to the semiconductor wafer, an elongated body portion extending away from the semiconductor wafer, and a tip portion; and a graphene electrode being made integral to the tip portions of the plurality of nanowires.

Many further features and combinations thereof concerning the present improvements will appear to those skilled in the art following a reading of the instant disclosure.

### DESCRIPTION OF THE FIGURES

In the figures,

FIG. 1 is an exploded view of an example of an electronic device having a substrate and an electronic component thereon, in accordance with one or more embodiments;

FIG. 2A is a schematic side view of a semiconductor wafer, in accordance with one or more embodiments;

FIG. 2B is a schematic side view of the semiconductor wafer of FIG. 2A, on which nanowires are grown, in accordance with one or more embodiments;

FIG. 2C is a schematic side view of the semiconductor wafer of FIG. 2B, showing tip portions of the nanowires brought closer together by an increase in width as the nanowires grow in length, in accordance with one or more embodiments;

FIG. 2D is a schematic side view of the semiconductor wafer of FIG. 2C, on which a buffer layer of aluminum nitride is made integral to the tip portions of the nanowires, in accordance with one or more embodiments;

FIG. 2E is a schematic side view of the semiconductor wafer of FIG. 2D on which an epilayer of a semiconductor material is deposited on the buffer layer of aluminum nitride, in accordance with one or more embodiments;

FIG. 3 is a flow chart of an example of a method of manufacturing a substrate for an electronic device, in accordance with one or more embodiments;

FIG. 4A is a sectional side view of an example of a substrate for a semiconductor device having a (111) silicon wafer and a self-organized gallium nitride nanowire template grown thereon, in accordance with one or more embodiments;

FIG. 4B is a sectional side view of the substrate of FIG. 4A, showing an initial growth of aluminum nitride atop the nanowire template, in accordance with one or more embodiments;

FIG. 4C is a sectional side view of the substrate of FIG. 4B, showing a buffer layer of aluminum nitride deposited atop the nanowire template, in accordance with one or more embodiments;

FIGS. 5A-D are reflection high-energy electron diffraction (RHEED) patterns, in which FIG. 5A is a RHEED pattern taken at the end of the growth of the nanowire template,

FIG. 5B is a RHEED pattern taken 30 minutes after the growth of the aluminum nitride, FIG. 5C is a RHEED pattern taken towards the end of the growth of the buffer layer of aluminum nitride, and FIG. 5D is a RHEED pattern taken during cooling down after the aluminum nitride growth (at ˜400° C.), respectively, in accordance with one or more embodiments;

FIGS. 6A and 6B are large-scale and small-scale scanning electron microscope

images of the substrate of FIG. 4C, showing overall smooth surface without cracks, in accordance with one or more embodiments;

FIG. 6C is a cross-sectional high-angle annular dark-field scanning transmission electron microscopy (STEM-HAADF) image of the substrate of FIG. 4C, in accordance with one or more embodiments;

FIG. 6D is an optical image of the substrate of FIG. 4C, in accordance with one or more embodiments;

FIG. 7 is a graph showing a X-ray diffraction (XRD) θ-2θ scan of the substrate of FIG. 4C, in accordance with one or more embodiments;

FIG. 8 is a room-temperature photoluminescence (PL) spectra of epilayers of aluminum gallium nitride with different aluminum contents grown on the buffer layer of aluminum nitride of the substrate of FIG. 4C, in accordance with one or more embodiments;

FIG. 9A is a schematic side view of another example of a substrate for a semiconductor device, the substrate having a (111) silicon wafer, a self-organized gallium nitride nanowire template grown thereon, a buffer layer of aluminum nitride atop the nanowire template and an epilayer of aluminum gallium nitride deposited on the buffer layer, in accordance with one or more embodiments;

FIG. 9B is a RHEED pattern of the substrate of FIG. 9A taken along the (1120) direction under metal-rich growth conditions, in accordance with one or more embodiments;

FIG. 9C is a STEM image of the substrate of FIG. 9A, in accordance with one or more embodiments;

FIG. 10 is a graph showing a X-ray diffraction (XRD) θ-2θ scan of the (002) diffraction plane of the epilayer of the substrate of FIG. 9A, in accordance with one or more embodiments;

FIG. 11A is a graph showing PL spectra of the epilayer of the substrate of FIG. 9A under different excitation wavelengths at room temperature, in accordance with one or more embodiments;

FIG. 11B is a graph showing the integrated PL intensity extracted from power-dependent PL spectra under different excitation wavelengths, in accordance with one or more embodiments;

FIG. 12A is a graph showing a generation rate as a function of the integrated PL intensity at various excitation wavelengths, with a curve fitted based on the Shockley-Read-Hall (SRH) model, in accordance with one or more embodiments;

FIG. 12B is a graph showing the calculated internal quantum efficiency (IQE) as a function of different generation rates at room temperature, in accordance with one or more embodiments;

FIG. 13A is a graph showing the emission peak energy as a function of power density, in accordance with one or more embodiments;

FIG. 13B is a graph showing the full-width at half-maximum (FWHM) as a function of pumping power density, in accordance with one or more embodiments;

FIG. 14A is a schematic view of an example of a Si substrate having grown thereon a thin pre-nanowire AlN buffer layer, a self-organized nanowire template and an AlN epilayer, in accordance with one or more embodiments;

FIG. 14B is an imagine of a RHEED pattern taken during the growth of the nanowire template of FIG. 14A, in accordance with one or more embodiments;

FIGS. 14C and 14D are images of RHEED patterns taken along the <1120> direction and <1100> direction, respectively, during the growth of the AlN epilayer of FIG. 14A, with arrows showing 2×6 RHEED reconstruction, in accordance with one or more embodiments;

FIG. 15A is an optical image showing the surface of the AlN epilayer of FIG. 14A, in accordance with one or more embodiments;

FIG. 15B is a large-scale SEM image of the substrate of FIG. 14A, in accordance with one or more embodiments;

FIG. 15C is an AFM image of the surface of the AlN epilayer of FIG. 14A, in accordance with one or more embodiments;

FIG. 15D is an SEM image of the AlN epilayer etched by KOH, taken with a tilt angle of 45°, in accordance with one or more embodiments;

FIG. 16A is a schematic view of an example of a AlGaN DH LED structure grown on top of an n-AlN/Si template, in accordance with one or more embodiments;

FIG. 16B is a graph showing room-temperature photoluminescence spectra of the AlGaN DH LED structure as a function of wavelength, in accordance with one or more embodiments;

FIG. 16C is a graph showing I-V characteristics of the AlGaN DH LED structure of FIG. 16A for a device size of 1 mm×1 mm and at a forward voltage of 12 V, in accordance with one or more embodiments;

FIG. 17A is a graph of room-temperature EL spectra of an AlGaN DH LED structure under different injection currents varying from 2 mA to 20 mA, in accordance with one or more embodiments;

FIG. 17B is a graph of room-temperature EL spectra taken up to the visible spectral range with currents varying from 1 mA to 12 mA, in accordance with one or more embodiments;

FIG. 17C is a graph showing light output power as a function of injected current, with an inset showing an optical image of the light emission, in accordance with one or more embodiments;

FIG. 17D is a schematic view of the setup for the angle dependent EL measurements, in accordance with one or more embodiments;

FIG. 17E is an emission pattern with the detection angle θ varying from −75° to 75°, the solid curve denoting the ideal Lambertian pattern for a device size of 1 mm×1 mm, in accordance with one or more embodiments;

FIG. 18A is a schematic view of an example of a AlGaN epilayer grown on a nanowire sandwich buffer layer, in accordance with one or more embodiments, in accordance with one or more embodiments;

FIG. 18B is a RHEED pattern captured during the growth of the AlGaN epilayer of FIG. 18A, in accordance with one or more embodiments;

FIG. 18C is an optical image of the surface of the AlGaN epilayer of FIG. 18A, in accordance with one or more embodiments;

FIG. 18D is a SEM image of the as-grown wafer, with the inset highlighting the cross-section, taken at a 45° tilting angle, in accordance with one or more embodiments;

FIG. 18E is an AFM image of the surface of the AlGaN epilayer of FIG. 18A, in accordance with one or more embodiments;

FIG. 19A is a graph showing room temperature PL spectra of AlGaN epilayers with various Al contents grown on Si substrate, in accordance with one or more embodiments;

FIG. 19B is a graph showing PL peak wavelength as a function of the Al content, in accordance with one or more embodiments;

FIG. 20A is a schematic view of an example of AlGaN DH LED device, in accordance with one or more embodiments, in accordance with one or more embodiments;

FIG. 20B is a graph showing current spreading length as a function of the forward current density with various ideality factors (n), in accordance with one or more embodiments;

FIG. 20C is a schematic view of an example layout of patterning mask for device fabrication, with the squares denoting p-contact, in accordance with one or more embodiments;

FIG. 21A is a graph showing I-V characteristics of an AlGaN DH LED with a device size of 1 mm×1 mm under a continuous-wave (CW) biasing, with the inset showing the I-V characteristics in a semi-logarithmic scale, in accordance with one or more embodiments;

FIG. 21B is a graph showing forward currents at a forward voltage of 12 V for devices with different sizes, with error bars indicating the current variation for devices with the same size, in accordance with one or more embodiments;

FIG. 22 is a graph showing room temperature EL spectra measured from AlGaN DH LEDs with different Al contents in the active region, in accordance with one or more embodiments;

FIGS. 23A to 23C show schematic views of exemplary structures having different AlN epilayers, in accordance with one or more embodiments, in accordance with one or more embodiments;

FIGS. 24A to 24F are SEM images of AlN epilayers grown under N-rich conditions

on a GaN nanowire template, with solid circles denoting the pits, and dashed circles denoting nanoclusters, in accordance with one or more embodiments;

FIGS. 25A and 25B are RHEED patterns taken during the growth of an AlN epilayer in the Al-rich condition along <1120> and <1100> directions, respectively, with arrows reflecting RHEED reconstruction, in accordance with one or more embodiments;

FIG. 25C is a SEM image of the as-grown surface of the AlN epilayer of FIG. 25A, in accordance with one or more embodiments;

FIG. 25D is a SEM image of the surface of FIG. 25C after 30 minutes KOH etching in harsh conditions, with dashed lines denoting a hexagonal shaped pit, in accordance with one or more embodiments;

FIG. 26A is a SEM image of GaN nanowires grown on a thin AlN buffer layer, in accordance with one or more embodiments;

FIG. 26B is a SEM image of GaN nanowires after KOH etching in mild conditions, in accordance with one or more embodiments;

FIGS. 27A and 27B are SEM images of the as-grown surface following test Structure B of FIG. 23B, and the surface after 15 seconds KOH etching in the harsh condition, respectively, with arrow marking a sample pit, in accordance with one or more embodiments;

FIGS. 27C and 27D are SEM images of the as-grown surface following test Structure C of FIG. 23C, and the surface after 1 minute KOH etching in the harsh condition, respectively, with dashed lines denoting a hexagonal shaped pit, in accordance with one or more embodiments;

FIG. 28A is a SEM image of an example as-grown AlGaN nanowire sample, taken at a 45° tilting angle, in accordance with one or more embodiments, in accordance with one or more embodiments;

FIG. 28B is a schematic view showing graphene transfer to a AlGaN nanowire sample, with the inset showing the nanowire sample layer-by-layer structure, in accordance with one or more embodiments;

FIG. 28C is a schematic view showing an example fabrication process for growing a graphene electrode onto a substrate, in accordance with one or more embodiments;

FIG. 29 is a graph showing Raman spectra for a graphene electrode and a bare AlGaN nanowire, in accordance with one or more embodiments;

FIG. 30A is a graph showing EL spectra of AlGaN nanowire devices emitting at different wavelengths with graphene electrode, with an inset showing an optical image of the light emission, in accordance with one or more embodiments;

FIGS. 30B and 30C are graphs showing light output power and EQE versus injection current for devices with graphene electrode and metal electrode, respectively, in accordance with one or more embodiments;

FIG. 31 is a graph showing I-V characteristics of devices with graphene electrode and metal contact, in accordance with one or more embodiments; and

FIG. 32 is a graph showing Raman spectrum of graphene electrode after electrical injection, in accordance with one or more embodiments.

### DETAILED DESCRIPTION

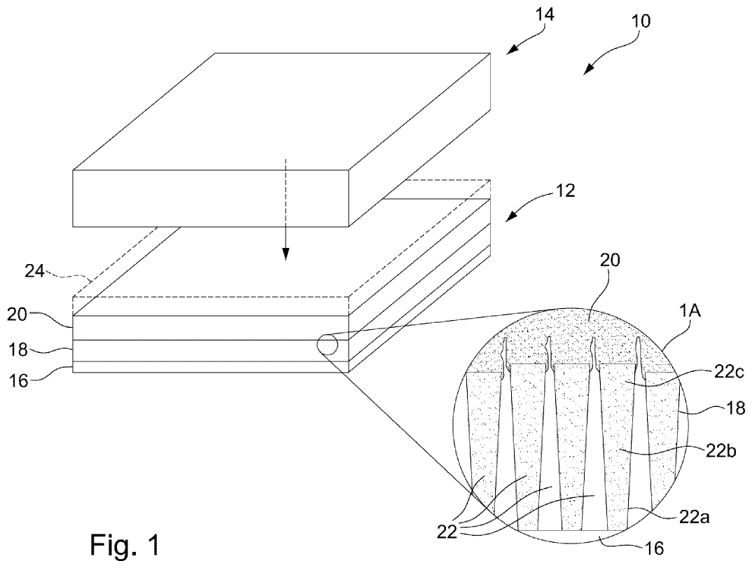

FIG. 1 shows an example of a semiconductor device 10, in accordance with one or more embodiments. The semiconductor device 10 has a substrate 12 on which is mounted a semiconductor component 14. The semiconductor component 14 can be any suitable type of electronic or optoelectronic component including, but not limited to, deep ultraviolet (UV) light emitting devices, high electron mobility transistors (HEMTs), microelectromechanical systems (MEMS), and surface acoustic wave (SAW) devices, or a combination thereof, to name a few examples.

As depicted, the substrate 12 has a semiconductor wafer 16, an intermediate nanowire layer 18 directly or indirectly mounted to the semiconductor wafer 16, and a buffer layer 20 of aluminum nitride (AlN) atop the intermediate nanowire layer 18. More specifically, and as best shown in inset 1A, the intermediate nanowire layer 18 has nanowires 22 each having in succession a base portion 22a mounted to the semiconductor wafer 16, an elongated body portion 22b extending away from the semiconductor wafer 16, and a tip portion 22c. As shown, the buffer layer 20 is made integral to the tip portions 22c of the nanowires 22 of the intermediate nanowire layer 18.

As shown in this embodiment, the substrate 12 can have one or more epilayer(s) 24 of a semiconductor material deposited on the buffer layer 20 of aluminum nitride. In this specific embodiment, the semiconductor material of the epilayer 24 is a group-III nitride semiconductor including, but not limited to, aluminum gallium nitride (AlGaN). The epilayer 24 is optional as it may be omitted in some embodiments. In some embodiments, the aluminum gallium nitride has an aluminum content varying between ˜35% and ˜70%. In some embodiments, the epilayer can be nitrogen-polar or metal-polar (e.g., aluminum-polar), depending on the method of fabrication as discussed below.

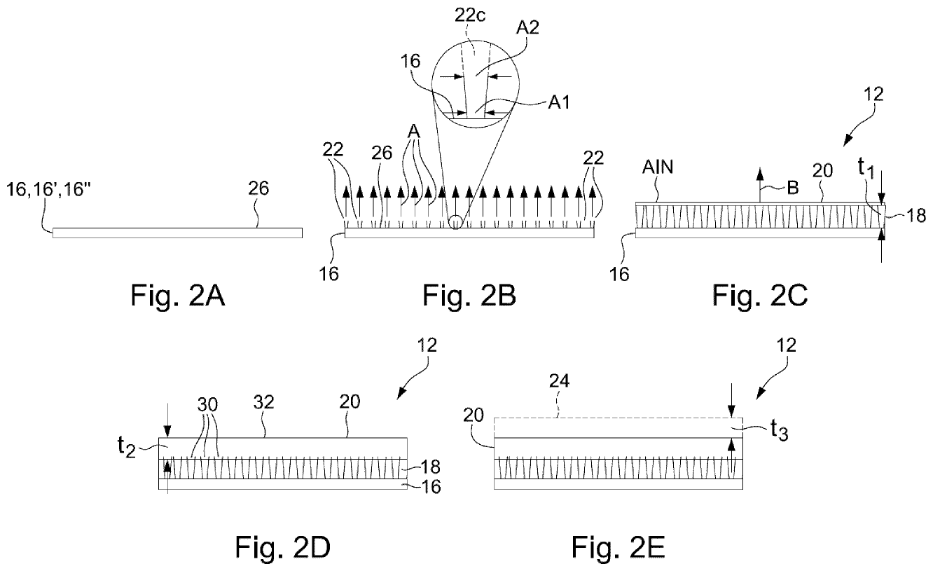

Reference is now made to FIGS. 2A through 2E which illustrate exemplary manufacturing steps for the substrate 12 of FIG. 1. As shown in FIG. 2A, a semiconductor wafer 16 is provided. In some embodiments, the semiconductor wafer 16 is a silicon wafer 16′. In some specific examples, the semiconductor wafer is a (111) oriented silicon wafer 16″. However, any semiconductor material can be used for the semiconductor wafer 16. Moreover, in embodiments where silicon wafer are used, any orientation silicon wafer may be used including, but not limited to, a (100) oriented silicon wafer, a (110) oriented silicon wafer, and the like. The silicon wafer 16′ can be made of p-type silicon, i-type silicon, n-type silicon, and/or any combination thereof, depending on the embodiment. The silicon wafer 16′ can be provided in the form of a portion or a whole of a 1-inch, 2-inch, 3-inch, 4-inch, 4.9-inch, 5.9-inch, 7.9 inch, 11.8 inch, 17.7-inch, 26.6 inch, or any other X-inch silicon wafer.

As best shown in FIG. 2B, nanowires 22 are grown on the semiconductor wafer 16. The nanowires 22 can be nanowires of any suitable type of semiconductor material. For instance, the nanowires 22 can be made of gallium nitride (GaN), indium gallium nitride (InGaN), aluminum gallium nitride (AlGaN), and/or a combination thereof. More specifically, under expected nanowire growth conditions, the nanowires 22 grow from an exposed face 26 of the semiconductor wafer in a direction normal to the exposed face 26 and pointing away from the semiconductor wafer 16, as illustrated by arrows A. In some embodiments, the nanowires 22 are grown in a self-organized manner, namely no nanowire template or mask lying atop the semiconductor wafer 16 is required for the growth of the nanowires 22. In some embodiments, the nanowires 22 are inverse-tapered such as their widths w increase along with their lengths l. More specifically, the nanowires 22 can have a cross-sectional area increasing from the semiconductor wafer 16 to the buffer layer. For instance, a first cross-sectional area A1 proximate the semiconductor wafer 16 is smaller than a second cross-sectional area A2 proximate to the buffer layer. With such inverse-tapered nanowires 22, the greater the length of the nanowires 22, the closer their tip portions 22c will be, until the tip portions 22c are adjoining with one another, and even touching, in some embodiments, to form the intermediate nanowire layer 18, such as shown in FIG. 2C. The intermediate nanowire layer can have a first thickness t1 ranging between about 10 nm and about 300 nm, preferably about 100 nm and about 250 nm and most preferably 150 nm. In some embodiments, a base layer of aluminum nitride is mounted atop the exposed face 26 of the semiconductor wafer 16. In these embodiments, the intermediate nanowire layer and more specifically the nanowires 22 are mounted to the base layer of aluminum nitride. In these later embodiments, the base layer can have a thickness ranging between about 0.5 nm and 10 nm, preferably between 0.5 nm and 5 nm and most preferably between 1 and 2 nm.

The buffer layer of aluminum nitride can be metal-polar or non-metal polar. For instance, the buffer layer can be made nitrogen-polar or aluminum-polar, depending on the growing conditions. Under given aluminum nitride deposition conditions, which for instance include a nitrogen-rich environment, aluminum nitride is gradually and uniformly deposited onto the tip portions 22c of the nanowires 22 until the buffer layer 20 of aluminum nitride is formed. Again, the thickness of the buffer layer 20 will increase in direction normal and opposite to the semiconductor wafer 16, as emphasized by arrow B. Preferably, aluminum nitride is deposited atop the intermediate nanowire layer 18 until a second thickness t2 is reached. In some embodiments, the second thickness t2 of the aluminum nitride is such that coalescence boundaries 30 are buried within the buffer layer 20 and terminate short of a distal face 32 of the buffer layer 20 such as shown in FIG. 2D. As such, in such embodiments, the buried coalescence boundaries 30 collectively leave the distal face 32 of the buffer layer 20 having a low defect density. For instance, in some embodiments, having a low defect density translates as having a defect density below a defect density threshold, where the defect density threshold would correspond to the defect density generally obtained using conventional techniques. The intermediate nanowire layer 18 and the buffer layer 20 of aluminum nitride can therefore collectively act as a structural defect filter for components atop, such as epilayer(s) and electronic components. An example of which includes the formation of a high quality epilayer of aluminum gallium nitride as described below. In some embodiments, the second thickness t2 of the buffer layer 20 can range between about 20 nm and about 2 μm, preferably about 20 nm and about 300 nm, more preferably between about 100 nm and about 250 nm and is most preferably about 150 nm. In some embodiments, the aluminum nitride is deposited such that is form a layer of high-quality N-polar buffer layer of aluminum nitride. In some embodiments, a graphene layer can be mounted directly to the buffer layer of aluminum nitride.

In some embodiments, an epilayer 24 of a semiconductor material is deposited on the buffer layer 20 of aluminum nitride. The epilayer 24 can be used as an interface to receive the semiconductor component directly thereon. In some embodiments, the semiconductor material of the epilayer 24 is a group-III nitride semiconductor. Examples of such group-III nitride semiconductor can include, but not limited to, aluminum gallium nitride. More than one epilayer of similar or dissimilar semiconductor materials may be applied to the buffer layer 20 of aluminum nitride. In some embodiments, the epilayer 24 has a third thickness t3 ranging between about 10 nm and about 2 μm, preferably between 10 nm and 1 μm, more preferably between about 100 nm and about 250 nm and most preferably is about 150 nm. As such, the substrate 12 can enable high-performance, highly compact, low-cost future-generation wide bandgap semiconductor electronic or optoelectronic devices in-situ on silicon. In some embodiments, a graphene electrode can be deposited on the buffer layer of aluminum nitride. or on the epilayer which can be advantageous at least in some embodiments, as described below.

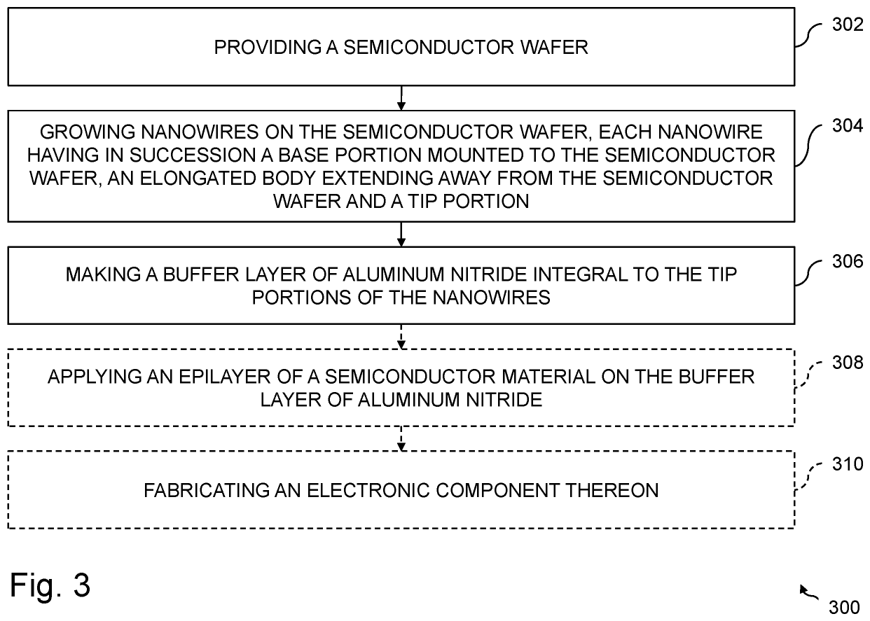

FIG. 3 shows an example of a method 300 of manufacturing a substrate for a semiconductor device.

As shown, at step 302, a semiconductor wafer is provided. As discussed above, the semiconductor wafer can be a semiconductor wafer of any semiconductor material and/or any size. In some embodiments, the semiconductor wafer is provided in the form of a silicon wafer, and the semiconductor device to be fabricated is therefore an aluminum nitride silicon-based semiconductor device.

At step 304, nanowires are grown on the semiconductor wafer to form an intermediate nanowire layer. The nanowires are grown in such a manner that each nanowire has in succession a base portion mounted to the semiconductor wafer, an elongated body portion extending away from the semiconductor wafer, and a tip portion. In some embodiments, aluminum nitride is deposited atop the tip portions of the nanowires until coalescence boundaries appearing in the buffer layer are buried therein, thereby leaving an exposed surface of a reduced defect density. The buffer layer of aluminum nitride can have a thickness ranging between about 20 nm and about 2 μm, preferably about 20 nm and about 300 nm, more preferably between about 100 nm and about 250 nm and is most preferably about 150 nm. In some embodiments, the step 304 of growing the nanowires is such that the nanowires increase in width as the nanowires increase in length so as to form inverse-tapered nanowires. In some embodiments, the step 304 of growing the nanowires includes a step of self-organizingly growing the nanowires on the semiconductor wafer, i.e., without requiring a nanowire template or mask, and free of any time- and cost-consuming lithography and etching fabrication step(s). In some embodiments, exemplary conditions for growing the nanowires and bringing them close to coalescence can include a low nitrogen flow rate around 0.3-0.7 sccm, a low substrate temperature of about 700-750 ° C., and a relatively high gallium metal supplies of about 0.8-1×10⁻⁷ Torr.

The technique with which the nanowires are grown on the semiconductor wafer can differ from one embodiment to another. In some embodiments, the nanowires are grown using a bottom-up approach in which the nanowire are synthetized by combining constituent adatoms atop a substrate in a self-organized manner (i.e., without a mask or template). In some embodiments, the nanowires are grown using a top-down approach in which a large piece of material is reduced to small nanowires by various means such as lithography, milling, thermal oxidation, and the like. Regardless of the approach, initial synthesis of the nanowires may often be followed by a nanowire thermal treatment step, often involving a form of self-limiting oxidation, to fine tune the size and aspect ratio of the nanowires. The growth of such nanowires can involve several common laboratory techniques, including suspension, electrochemical deposition, vapor deposition, vapor-liquid-solid (VLS) growth, solution-phase synthesis, non-catalytic growth, DNA-template metallic nanowire synthesis, and crack-defined shadow mask lithography, to name a few examples.

At step 306, a buffer layer of aluminum nitride is made integral to the tip portions of the nanowires. The step 306 can be performed under given environmental conditions slowing aluminum adatom migration within the buffer layer including nitrogen-rich conditions, for instance. In these embodiments, the buffer layer is made with a non-metal surface termination, preferably aluminum nitride nitrogen-polar. In some other embodiments, the buffer layer can be made with a metal surface termination, preferably aluminum nitride aluminium-polar. Examples of environmental conditions include low temperature, nitrogen-rich environment, an aluminum-rich environment, or any combination thereof. As such, migration of the aluminum adatom along a plane of the buffer may be favored, which can in turn contribute to burying coalescence boundaries forming within the buffer layer as the buffer layer is deposited or otherwise made. The aluminum nitride can be deposited on the intermediate nanowire layer using any suitable deposition techniques including, but not limited to, metal organic chemical vapor deposition (MOCVD), molecular beam epitaxy (MBE), electron cyclotron resonance dual-ion beam sputtering, and pulsed laser ablation. In some embodiments, the step 306 of making the buffer layer includes a step of gradually and uniformly depositing aluminum nitride atop the tip portions of the nanowires while heating the substrate at a temperature below a given temperature threshold. In some embodiments, the temperature threshold is below about 1000° C., preferably between about 960° C. and about 810° C., and most preferably between about 960° C. and 850° C. below about 850° C. and most preferably about 810° C. As such, it is appreciated that the deposition of the aluminum nitride can be performed at temperature that are lower than the typical aluminum nitride nanowire deposition temperature. In some embodiments, the deposition of the aluminum nitride can be performed at a nitrogen flow rate higher than a nitrogen flow rate threshold. The nitrogen flow rate threshold can correspond to the nitrogen flow rate used for conventional aluminum nitride thin film deposition. For instance, the nitrogen flow rate threshold can range between about 0.3 sccm and about 1.5 sccm, and is preferably 0.3 sccm. As such, the buffer layer of aluminum nitride may be nitrogen-polar, in some embodiments. It is intended that by exploiting the slow aluminum adatom migration under the given environmental conditions, the lateral growth (i.e., growth radially outwardly with respect to the nanowire axis) can be enhanced which in consequence promotes a coalescence process of aluminum nitride. As such, the intermediate nanowire layer and the aluminum nitride thin layer composite act as a structural defect filter for atop device component layers. In some embodiments, exemplary conditions for growing the buffer layer of aluminum and enabling the burial of the coalescence boundaries can include a low substrate temperature between about 810-900° C., a high nitrogen flow rate of about 1-.5 sccm, and a low aluminum metal supplies of about 1-4×10⁻⁸ Torr.

At step 308, an epilayer of a semiconductor material is applied on the buffer layer of aluminum nitride. In some embodiments, the semiconductor material of the epilayer is a group-III nitride semiconductor such as aluminum gallium nitride. The step 308 is only optional as it can be omitted in some embodiments. It is intended that the deposition of the epilayer(s) may also be performed in a nitrogen-rich environment, with a nitrogen flow higher than the nitrogen flow threshold. The epilayer(s) may also be nitrogen-polar.

At step 310, an electronic component is fabricated on the buffer layer of aluminum nitride. In some embodiments, the electronic component is directly deposited or otherwise built on the buffer layer whereas in some embodiments the electronic component can be indirectly deposited or otherwise built on the buffer layer via the optional epilayer(s).

### EXAMPLE 1

### Molecular Beam Epitaxial Growth of High-Quality AlN Thin Films on Si Through Exploiting Low Al Adatom Migration in the Nitrogen Rich Environment on a Nanowire Template

Aluminum nitride (AlN) on Si is an appealing platform for semiconductor electronic and optoelectronic devices, not only for the availability of high crystalline quality Si substrates at a low cost and the dominant role of Si on modern semiconductor device technologies, but also for the technical importance of AlN for a wide range of applications, such as deep ultraviolet (UV) light emitting, high electron mobility transistors (HEMTs), microelectromechanical systems (MEMS), and surface acoustic wave (SAW) devices. Moreover, obtaining high-quality AlN on Si represents the first step towards III-nitrides-based electronic and optoelectronic devices on Si. For example, AlN is an important buffer layer for aluminum gallium nitride (AlGaN) deep UV light-emitting devices on Si; and there is a direct correlation of the device performance improvement to the improvement of the AlN buffer layer quality.

In the past the growth of AlN on Si has attracted significant attention and efforts; and various techniques have been used for the growth of AlN on Si, including molecular beam epitaxy (MBE), metal-organic chemical vapor deposition (MOCVD) and/or metalorganic vapor phase epitaxy (MOVPE), and pulsed laser deposition (PLD). Despite the progress, it remains challenging today to grow high-quality AlN thin films on Si, due to the large thermal and lattice mismatches between AlN and Si.

Different from the growth of GaN on Si, wherein the tensile strain can be compensated by using AlN and/or AlGaN buffer layer that introduces compressive strain, for the growth of AlN on Si, there are no such strain compensative buffer layers due to the unavailability of a material that can be grown epitaxially but with a smaller lattice constant than that of AlN.

Today, to obtain high-quality AlN buffer layer, different techniques have been developed, such as using a NH₃ pulsed-flow growth mode in a MOCVD chamber, using silicon-on-insulator (SOI) wafers, using Si substrates with a different orientation, and exploit the lateral epitaxial overgrowth (LEO) on patterned substrates. Among various approaches, LEO so far has produced promising results. For example, using micro-circle patterned Si substrates, several um (˜6-8 μm) thick crack-free AlN buffer layer with dislocation densities as low as mid-10⁷ cm⁻² have been demonstrated; nonetheless, it is a long growth process as thick layers are required for high quality for large pattern spacings. To reduce growth duration, nano-stripe patterned Si substrates have also been investigated; however, the quality is not comparable to the use of micro-circle patterned Si substrates. Very recently, with the use of nano-circle patterned Si substrates, a relatively thin AlN buffer layer (˜2 μm) has been obtained with with a narrow full width at half maximum (FWHM) of as low as 409 arcsec for the (002) plane measured from X-ray diffraction (XRD), suggesting a low dislocation density.

Though the progress of using patterned Si substrates, it remains a costly process. Regardless of using micro-scale or nano-scale patterning, additional lithography and etching processes that are required for the wafer preparation add time- and dollar-cost. Moreover, for micro-scale patterned substrates, a long growth duration is required, adding manufacturing cost. In addition, although using nano-scale patterned substrates, the thickness of AlN buffer layer is reduced to 2 μm, it remains thick and limits the compactness of the devices.

In this example, a different approach to fabricate AlN buffer layer on Si is presented. This new approach exploits the slow Al adatom migration in the nitrogen (N)-rich environment on a nanowire template and allows the achievement of ultrathin AlN buffer layer on Si. The detailed electron microscopy characterizations suggest that the AlN thin film is relatively smooth. XRD experiments further indicate that such an AlN thin film, with a thickness of less than 180 nm, can have a narrow FWHM of 972 arcsec from the (002) plane, confirming a high crystalline quality. Further using such an AlN thin film as a buffer layer, deep UV emitting AlGaN epilayers have been further demonstrated on Si.

In this example, the AlN sample was grown by radio frequency (RF) plasma-assisted MBE on Si (111) substrates. Standard solvent cleaning and hydrofluoric acid etching were performed before loading the substrates to the MBE system. Prior to the growth, the wafer was thermally outgassed in situ for 15 min. This was followed by the growth of a GaN nanowire template under the N-rich condition. The growth parameters for AlN thin film included a substrate temperature of 810° C., a N flow rate of 1 sccm, and an Al flux ˜2×10⁻⁸ Torr. Compared to the typical growth temperature of AlN nanowires, this temperature is considerably lower. The detailed structural properties were characterized by scanning electron microscopy (SEM) and cross-sectional scanning transmission electron microscopy (STEM). The specimen for the cross-sectional imaging was prepared by focused ion beam (FIB) etching, wherein a platinum (Pt) protection layer was coated on the sample surface. The XRD θ-2θ scan was used to check the crystalline quality of the as-grown wafer.

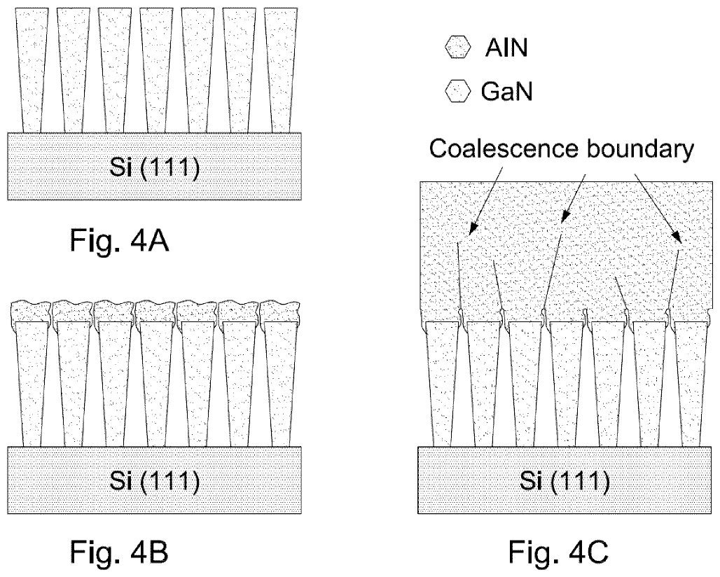

FIGS. 4A-D illustrate the conceptual growth process. First, the growth process starts with a GaN nanowire template that is self-organized and is free of any time- and cost-consuming lithography and etching processes; and by optimizing the growth condition, the individual GaN nanowires are brought close to coalescence (FIG. 4A). Then, the growth of AlN is initiated. By exploiting the slow Al adatom migration in the N-rich environment at a moderate growth temperature, the lateral growth is enhanced which in subsequence promotes a coalescence process of AlN (FIG. 4B). In the end, beyond the coalescence region, a high-quality AlN thin film can be obtained (FIG. 4C).

There are a few key elements that ensure the success of the above conceptual growth process. First of all, as the starting point of this approach is nanowires, the strain induced by Si substrates can be well relaxed at the nanowire growth stage; and high quality nanowires have been shown on Si substrates previously. Furthermore, previous studies have shown that for the nanowire coalescence process, structural defects are mainly localized around the coalescence boundary, and the regions beyond the coalescence are of high quality; this allows the achievement of high quality material within a small thickness.

More importantly, the slow Al adatom migration in the nitrogen (N)-rich environment is exploited. It is well-known that the slow migration of Al makes the growth of AlN more challenging than GaN, and significant efforts have been working to improve the Al migration, such as the growth of AlN nanowires on a GaN nanowire template. Here, the process utilizes Al low migration, rather than work against it: the low Al adatom migration leads to a low vertical growth rate, and can thus mitigate the adverse effects of using the self-organized nanowires for obtaining high-quality thin films, such as the non-uniform nanowire height and the misorientation of individual nanowires with respect to the substrate. As a consequence, the coalescence of AlN can lead to high-quality AlN thin films.

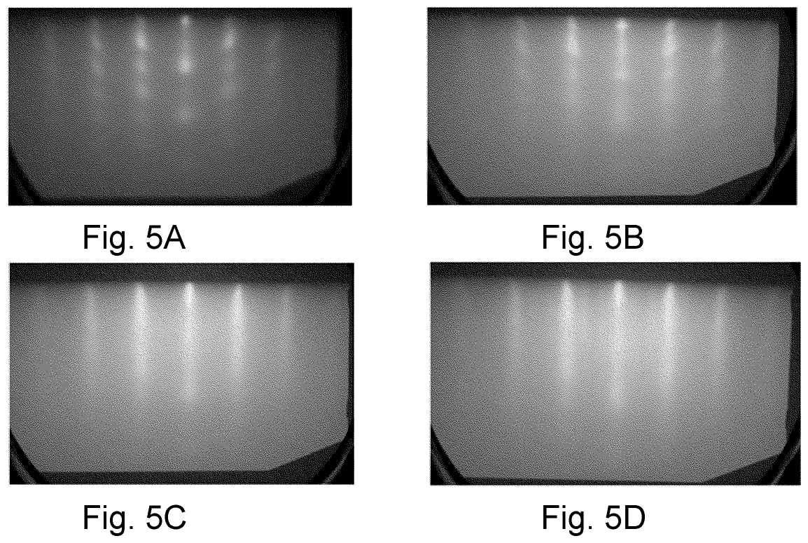

FIGS. 5A-D show the reflection high-energy electron diffraction (RHEED) patterns along (1120) direction at different growth stages. Shown in FIG. 5A, towards the end of the growth of the GaN nanowire template, the spotted dots, which correspond to the three-dimensional (3D) growth of vertical-aligned GaN nanowires under the N-rich condition, became connected. This indicates a high density of nanowires and/or the start of coalescence. After starting the growth of AlN for 30 min, the RHEED pattern evolved into streaks, with the presence of certain spotty features (FIG. 5B). Towards the end of the growth, a completely streaky RHEED pattern was observed (FIG. 5C), suggesting the formation of a smooth planar thin film. Moreover, a surface reconstruction was observed during cooling down the wafer: as shown in FIG. 5D, a RHEED pattern taken at 400° C., a clearly 3×3 RHEED pattern was observed, indicating that the presented AlN film is N-polar. This is further confirmed by the KOH wet etching experiments.

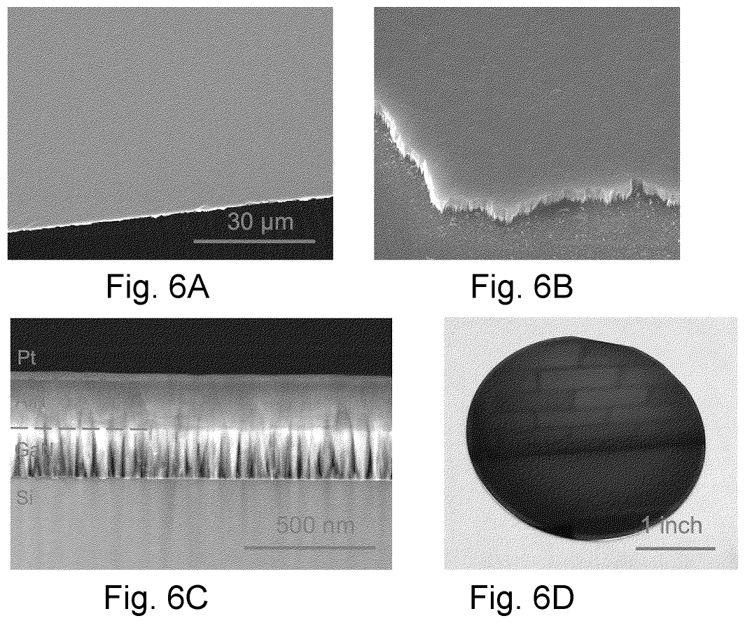

The surface morphologies and structural properties of the AlN thin film are then further characterized. FIG. 6A illustrates the large-scale SEM image of the sample. Further shown by FIG. 6B, the film shows a relatively smooth surface without hillocks, in contrast to the previously reported GaN thin films through the coalescence of self-organized GaN nanowires. This can be understood that, as Al has a much slower adatom migration compared to Ga in the N-rich environment, the vertical growth rate of AlN is much slower; and thus, the adverse effects of using the self-organized nanowires for obtaining thin films through a coalescence process, such as the non-uniform nanowire height and the misorientation of individual nanowires with respect to the substrate, can be well mitigated.

FIG. 6C shows the cross-sectional STEM high angular annular dark-field (HAADF) image of the sample, with each layer labeled. The GaN nanowire template exhibits a relatively uniform height and vertical alignment, as well as a strong tapering that minimizes the nanowire spacing and/or enables a certain degree of coalescence before the growth of AlN, which is consistent with the RHEED pattern (FIG. 5A). After starting the growth of AlN, the coalescence became more noticeable and completed before the end of the growth. An optical image of such an AlN on Si wafer is shown in FIG. 6D. It is seen that the sample is mirror-reflective and uniform without any color rings.

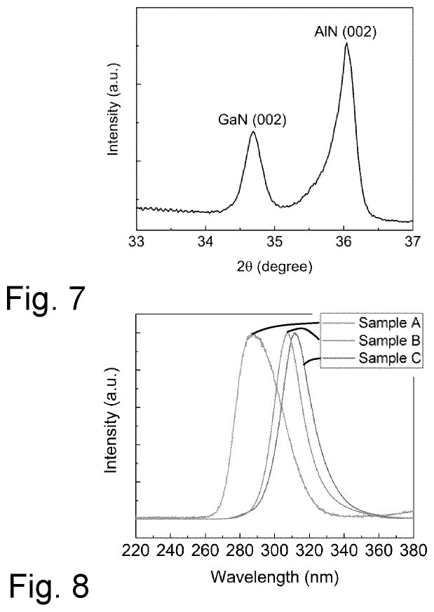

The crystalline quality of the AlN thin film is further investigated through XRD experiments. FIG. 7 is a θ-2θ scan over a scanning angle of 33° to 37° . The two diffraction peaks are from GaN (002) plane and AlN (002) plane at 2θ=34.68° and 36.04°, respectively. The FWHM of the AlN (002) diffraction peak is derived to be around 972 arcsec) (0.27°). The FWHM of diffraction peaks is known as a figure of merit for the crystalline quality, e.g., a reflection of dislocation densities, the FWHM from the sample in the present example is hence compared with the previously reported values. One could appreciate that the AlN (002) FWHM shows an increasing trend as the AlN thickness decreases—a natural reflection in the increase of dislocation densities as the thickness reduces. For the previously reported AlN thin films with similar thicknesses compared with the sample in the present study, the FWHM is in the range of 1250 to 2000 arcsec, significantly higher than that measured from the AlN thin film in the present study. It is further noted that the nominal thickness of 180 nm includes the portion wherein the coalescence is not complete, and hence the thin film layer thickness should be much less than this value. Further improvement of the AlN buffer layer quality can be expected as the increase of the thickness.

In the end, it is shown that using such an AlN thin film as a buffer layer, AlGaN epilayers with different emission wavelengths can be obtained. All the AlGaN epilayers were grown under metal-rich conditions at a substrate temperature of 720° C. FIG. 8 illustrates the normalized PL spectra of three samples with different Al compositions excited by low power at the room temperature. It is seen that the emission wavelengths are 287 nm, 307 nm, and 312 nm for Sample A-C, respectively, covering the range of nearly the entire UV-B band. The Al content was further estimated using the Vegard's law with E_{g} (GaN)=3.4 eV, E_{g} (AlN)=6.2 eV, and bowing parameter of 1 eV, which gives Al contents of around 0.36, 0.30, and 0.27, respectively.

In summary, a new approach to obtained AlN thin films on Si was introduced. This new method exploits the low migration mobility of Al under the N-rich environment on a nanowire template. The obtained AlN thin film is relatively smooth and XRD experiments further indicate a narrow (002) peak, being the lowest reported for AlN thin films on Si with similar thicknesses. Compared to the previous approaches of growing AlN thin films on Si, this approach enables compact, low-cost, and quality highly reproducible AlN thin films on Si that can be fabricated rapidly. Further with the demonstration of AlGaN epilayers with the room-temperature deep UV emission using such an AlN thin film as a buffer layer, as well as the N-polarity of the AlN thin film that brings additional benefits to electronic and optoelectronic devices, such as the lower contact resistance and the reduced efficiency droop, this AlN on Si technology by MBE could enable high-performance, highly compact, and low-cost III-nitride optoelectronic and electronic devices in situ on Si.

### EXAMPLE 2

### Structural and Optical Properties of Algan Epilayers on Si by Molecular Beam Epitaxy Using an AlN Buffer Layer on a Nanowire Template

Over the past decades, aluminum gallium nitride (AGaN) alloys grown have attracted great attention due to their direct, ultra-wide, and tunable bandgap energies, as well as promising future in developing ultraviolet (UV) phototransistors, solar-blind photodetectors, and more importantly, semiconductor UV light-emitting devices, such as LEDs and laser diodes (LDs), which are positioned to replace conventional mercury based UV light emitting technologies that have bulky size, low efficient, and are environmental hazards.

Hitherto, AlGaN based optoelectronic devices are developed mainly on foreign substrates, such as sapphire, AlN on sapphire template, free-standing GaN substrates, and bulk AlN substrates. Compared with other these foreign substrates, Si substrate promises several advantages: 1) Low cost. This is in particular compared to the expensive free-standing GaN and bulk AlN substrates. 2) Si has excellent electric and thermal conduction. 3) High-quality Si substrates can be available at 12 inches at a low cost, taking the advantage of mature processing technologies, whereas other foreign substrates cannot. 4) Using Si as the substrate is an appealing route to the fabrication of flip-chip UV LEDs due to the easy removal of Si by wet etching. This is in contrast to the removal of sapphire substrates wherein the laser lift-off process can cause the degradation of the device. 5) The development of AlGaN UV LEDs on Si naturally allows the integration of Si-based electronics.

However, the growth of high-quality AlGaN epilayers on Si substrates remains challenging, mainly due to the large lattice mismatch (˜17%) and thermal mismatch (˜53%) between AlGaN and Si, which lead to materials with large defect densities and cracks. Today, different techniques have been developed to improve the material quality. The most common approach is to use AlN buffer layer. AlN buffer layer has been developed long time ago to enable high quality GaN. The use of AlN can introduce compressive strain and thus compensate the tensile strain of AlGaN layers on Si, promising crack-free AlGaN epilayers on Si. However, to obtain high-quality AlN buffer layer is not an easy task. In the past different techniques have been developed such as using super-lattices (SLs) and NH₃ pulsed-flow growth mode. These techniques, although can lead to crack-free AlN buffer layer, but the thickness is generally small; and dislocation densities have remained high—to reduce which a thick layer is required and cracks are generated. To mitigate this issue, AlN buffer layer by laterial epitaxial growth (LEO) growth techniques has been developed, and yielded several μm thick crack-free AlN buffer layer with dislocation densities as low as mid-10⁷ cm⁻². This approach has enabled AlGaN UV LEDs down to 256 nm on Si with optical output powers in the milli-watt range.

Another alternative approach is to use Al(Ga)N superlattices (SLs). In general, SLs not only compensate in-plain strain but also serve as dislocation density filters. Previously, SLs have been successful in improving the quality of III-nitrides on foreign substrates. This technique has been adopted to the growth of AlGaN on Si. The typical strategy is to deposit Al(Ga)N SLs after an AlN layer. Using AlN and AlGaN SLs buffer layers, high quality thick (˜2 μm) AlGaN epilayers have been achieved on Si, with an XRD (002) FWHM of 499 arcsec.

Alternatively, followed by thin AlN layer, compositionally graded AlGaN buffer layers have also been used to develop high quality AlGaN layers on Si. Phenomenally, with such compositionally graded AlGaN buffer layers, electrically injected lasers on Si in the near UV band have been demonstrated.

Despite the progress, there are common issues of the current approaches, i.e., in order to obtain low dislocation densities, thick buffer layers are required—often several pm thick, which not only limits the device compactness, but also several issues. For example, although AlN buffer layer on patterned substrate has led to device quality AlGaN epilayers, the use of patterned Si substrates add additional time- and dollar-cost in the wafer preparation process. For the use of multiple buffer layers, the growth process generally takes a long time due to the complicated buffer layer structures. In addition, the multiple buffer layer induced wafer bowing also affects the uniformity across the wafer during the growth. As such, it is desirable to reduce the total thickness of the epilayers.

Recently, a new AlN buffer layer technology on Si is presented in this example. Such an AlN buffer exploits the low Al adatom migration in the nitrogen rich environment on a nanowire template. As the starting point of this approach is nanowires, the strain induced by Si substrates can be well relaxed at the nanowire growth stage; and previously high quality nanowires have been shown on Si substrates. Moreover, previous studies have shown that for the nanowire coalescence process, structural defects are mainly localized around the coalescence boundary, and the regions beyond the coalescence are of high quality. Indeed, a high quality AlN buffer layer has been obtained with this approach in this example, with a nominal thickness of less than 200 nm. The growth of AlGaN epilayers with varying Al contents on Si using such an AlN buffer has also been demonstrated.

In this example, a detailed study on the structural properties of AlGaN epilayers grown on Si using such an AlN buffer layer is presented. Moreover, it is further noted that, compared to many studies on the internal quantum efficiency (IQE) of AlGaN epilayers and quantum wells on sapphire and/or AlN-on-sapphire template, such studies are barely carried out on AlGaN epilayers grown on Si, which are nonetheless critical to further improve the device performance on Si. Therefore, in this work, there is also presented a detailed study on the optical properties of such AlGaN epilayers, including the analysis on the intrinsic excitation-dependent IQE at the room temperature and the efficiency droop.

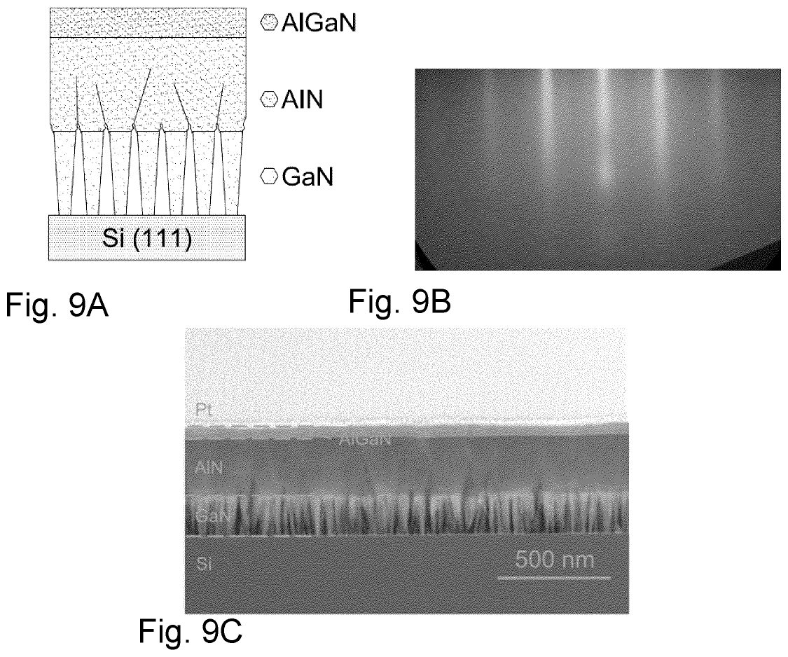

In this study, the sample was grown by radio-frequency (RF) plasma-assisted MBE. The schematic of such an AlGaN sample is shown in FIG. 9A, which starts with a GaN nanowire template, followed by the growth of AlN buffer layer through a coalescence process, and then the final AlGaN epilayer on top. Both the GaN nanowire template and the AlN buffer were grown under nitrogen (N)-rich conditions. The substrate temperatures for the two layers are 720° C. and 810° C., respectively. The AlGaN epilayer was grown under metal rich conditions at a substrate temperature of 720° C. The Ga flux and Al flux were 1×10⁻⁷ Torr and 2×10⁻⁸ Torr, respectively.

The surface morphology and the crystalline quality of the AlGaN epilayer was characterized by scanning electron microscopy (SEM) and cross-sectional scanning transmission electron microscopy (STEM), as well as X-ray diffraction experiments. The specimen for the cross-sectional imaging was prepared by focused ion beam (FIB) etching, wherein a platinum (Pt) protection layer was coated on the sample surface. The optical properties of the AlGaN epilayer were studied by the power-dependent photoluminescence (PL) experiments at the room temperature. A 213 nm pulsed laser was used as the excitation source, with a pulse of 7 ns and a repetition rate of 100 Hz. A UV neutral density (ND) filter was used to adjust the laser excitation power. The laser light was focused to the sample surface through a silica focus lens, and the emitted light from the sample was also collected by a silica focus lens, which was further coupled to an optical fiber and detected by a deep UV spectrometer.

FIG. 9B shows the reflection high-energy electron diffraction (RHEED) pattern taken during the growth of the AlGaN epilayer along (1120) direction. It is seen that bright and streaky RHEED pattern is observed, indicating a two-dimensional (2D) growth under the metal-rich condition and a relatively smooth AlGaN thin film. The cross-section of the sample is further examined by STEM. FIG. 9C shows the cross-sectional STEM HAADF image, with each layer labeled. It is seen that the coalescence of AlN is complete within the AlN buffer layer, with a few coalescence boundaries (marked by arrows). It is confirmed confirmed in the previous example that such an AlN buffer layer is of high quality. It is also seen that the AlGaN layer has a thickness of around 50 nm and is relatively smooth.

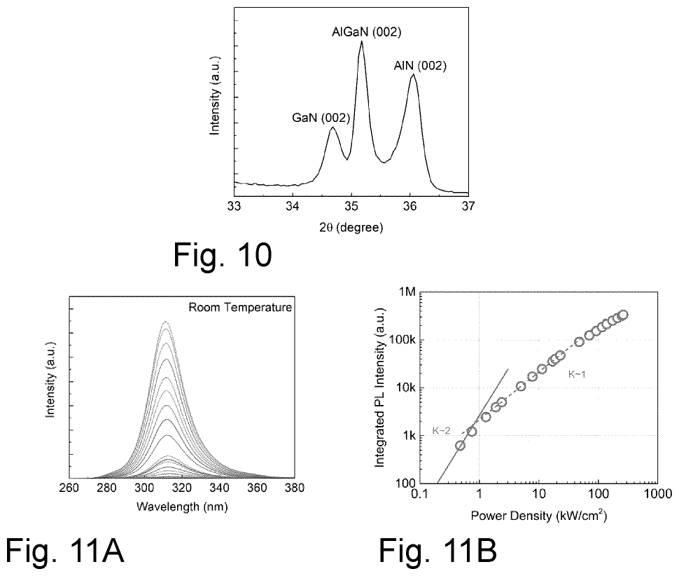

The crystalline quality of the AlGaN epilayer was further investigated by XRD θ-2θ scans over a range from 33° to 37°. FIG. 10 shows the presence of the diffraction peaks at 34.68, 35.17°, and 36.05°, which correspond to GaN (002), AlGaN (002), and AlN (002) diffraction planes, respectively. Among those, the AlGaN (002) plane gives a FWHM value of 852 arcsec (0.2366°). One could appreciate that the FWHM increases as the thickness of the AlGaN thin film reduces, suggesting an increased dislocation density and a degraded crystalline quality. In contrast, the result from the present work is comparable to the film with hundreds of nm thickness and much superior to those with a similar thickness, suggesting that low dislocation density and high crystalline AlGaN epilayer can be obtained at a small thickness with the use of the AlN buffer layer through a coalescence process on a nanowire template. Further improved crystalline quality is expected with the increase of the thin film thickness. To the inventor's best knowledge, the FWHM of AlGaN (002) in the present work is the lowest obtained for AlGaN epilayers at a similar thickness.

The optical properties of such AlGaN epilayer were further examined by the power-dependent PL experiments at the room temperature. FIG. 11A shows the PL spectra under different excitations. The emission peak is around 313 nm at low excitations, from which the Al composition of the AlGaN epilayer is estimated using Vegard's law. By assuming the bowing parameter to be 0.7 eV, an Al composition of ˜0.26 was derived. It is also noticed that the spectral linewidth is relatively broad (FWHM of 24 nm at low excitations). This linewidth is noticeably broader than the previously reported AlGaN quantum wells, and comparable to the linewidth of AlGaN nanowires, which could indicate the presence of compositional inhomogeneity and/or compositional fluctuations.

FIG. 11B illustrates the log-log relation between the integrated PL intensity IPL and the excitation power density. Slopes k=2 and k=1, which correspond to the nonradiative recombination and radiative recombination process, respectively, are also shown. It is seen the PL emission is mainly dominated by the radiative recombination process, without a clear sign of the nonradiative recombination dominated process, suggesting a high IQE and low dislocation densities—consistent with the narrow XRD (002) FWHM.

The excitation-dependent room-temperature IQE of the AlGaN epilayer is studied by considering Shockley—Read—Hall (SRH) nonradiative recombination (An), bimolecular radiative recombination rate (Bn²), and the high-order nonradiative recombination rate (Cn³), where A,B,C are the respective coefficients, and n is the carrier concentration at different excitations. Using the steady-state approximation, the carrier generation rate (G) is equal to the total recombination rate (R), i.e., G=R=An+Bn²+Cn³. The generation rate G can be calculated experimentally as follows:

$$G = \frac{{P}_{Laser} ( 1 - {R}_{F} ) α}{{A}_{spot} hv} , \qquad ( 1 )$$

where Aₛₚₒₜ (9.0×10⁴ μm²) is laser beam spot size, hv (5.82 eV) is the

photon energy of the 213 nm laser, P_{Laser} is the peak pumping power under various excitations, a (2.5×10⁵ cm⁻¹) is the absorption coefficient of the epilayer, and R_{F} is the reflectance (18%) estimated by Fresnel's law. On the other hand, taking the integrated PL intensity I_{PL} in the form of I_{PL}=γBn², where I_{PL} can be extracted from the power-dependent PL spectra and γ is an experimental parameter that is related to the active region volume, PL collection efficiency, and light extraction efficiency, the carrier concentration can be expressed as

$$n = \sqrt{\frac{{I}_{PL}}{γ B}} ;$$

therefore, the generation rate G takes the form:

$$G = \frac{A}{\sqrt{B γ}} \sqrt{{I}_{PL}} + \frac{1}{γ} {I}_{PL} + \frac{C}{\sqrt{{( N γ )}^{3}}} \sqrt{{I}_{PL}^{3}} , \qquad ( 2 )$$

and IQE can be calculated via,

$$IQE = \frac{{Bn}^{2}}{An + {Bn}^{2} + {Cn}^{3}} = \frac{{I}_{PL}}{γ G} . \qquad ( 3 )$$

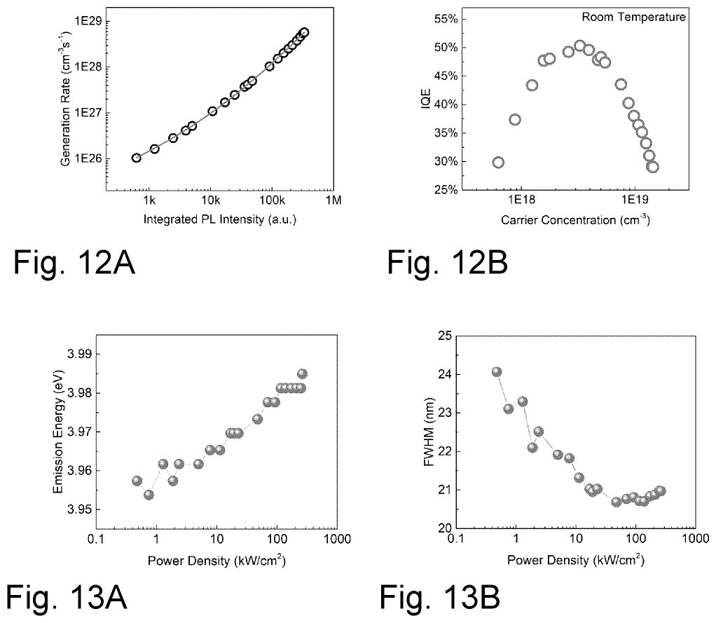

FIG. 12A shows the experimentally determined G as a function of I_{PL}, extracted from FIG. 11A, in a log-log scale, together with a fitting curve using Eq. (2).

It is seen that excellent fitting is obtained. This allows one to determine y, and thus calculate IQE via Eq. (3). FIG. 12B shows the calculated as a function of the generation rate. It is seen that a maximum IQE of around 50% is reached. In the derivation of IQE with Eq. (3), as A, B, and C coefficients were not involved, it thus reflects the intrinsic IQE of the present AlGaN. Carrier density is further estimated at peak IQE by taking B of 8×10⁻¹¹ cm³s⁻¹ following recent studies for AlGaN epilayers ata similar wavelength, which yields a carrier density n of 3×10¹⁸ cm⁻³. This IQE is noticeably higher than the previously reported AlGaN epilayers grown on sapphire and/or AlN-on-sapphire template, which is largely attributed to a better crystalline quality achieved by using the high quality AlN buffer layer. This high IQE is also consistent with the slope suggested in FIG. 11B and the narrow XRD (002) FWHM.

An efficiency droop is also seen at mid excitations. Hitherto, compared to many studies on the efficiency droop of InGaN based quantum wells and epilayers, the efficiency droop on the AlGaN based materials is much less studied. Limited studies have suggested carrier delocalization, Auger recombination, heating effect, saturation of the radiative recombination due to phase filling, and carrier leakage as the possible mechanism for AlGaN based materials and devices. Carrier leakage is more relevant to quantum wells and/or under electrical injection, and is thus not likely related to the droop in the present study. Moreover, due to the use of pulsed laser, heating effect is also not likely the cause.

To further examine carrier delocalization, the extracted PL peak energy and spectral FWHM are plotted as a function of the power density in FIGS. 13A and 13B, respectively. It is seen that as the excitation increases, the PL peak energy is blue-shifted by ˜28 meV, accompanied by a reduction of FWHM. This blueshift and FWHM narrowing is consistent with the electrostatic screening of the Stark effect (as the carrier density increases), mainly attributed to the electric field induced by the piezoelectric polarization, given that the present AlGaN layer is around 50 nm and is thus compressively strained. This leads to an increase of IQE. Similar effects have been reported previously in III-nitride quantum wells and nanowire structures. These features are nonetheless inconsistent with carrier delocalization, in which a blueshift and FHWM increase are expected. However, considering the broad PL spectra, compositional fluctuations are expected and thus carrier delocalization could contribute to the efficiency droop. In this case, the failure in observing a clear increasing trend of FWHM could be related to the strain-induced piezoelectric field. Previous studies have indicated that strong strain-induced piezoelectric field could screen the observation of the FWHM increase.

Lastly, the estimated peak IQE occurs at a carrier density of 3×10¹⁸ cm⁻³, which might indicate Auger is not likely the dominant role for the droop onset. If taking the lower bound B value for AlGaN epilayers, the carrier density at peak IQE is ˜6×10¹⁸ cm⁻³, again suggesting Auger might not be the cause. Previous studies on the efficiency droop of AlGaN epilayers on sapphire have suggested that Auger only plays a role if carrier density is 10²⁰ cm⁻³. Nonetheless, the current study cannot rule out saturation of radiative recombination.

In conclusion for this example, a detailed study has been performed on the structural and optical properties of AlGaN epilayers on Si, which were grown by MBE and on an AlN buffer through a coalescence process on a nanowire template. A relatively smooth film was obtained. XRD scans further show a low (002) FWHM, suggesting a low dislocation density and a high crystalline quality. Further combining the excitation dependent PL and a theoretical model, the intrinsic room-temperature IQE of such AlGaN epilayers is derived, which is peak at ˜50%, with an estimated carrier density of 3×10¹⁸ cm⁻³. This IQE is significantly improved compared to the previously reported AlGaN epilayers on sapphire and/or AlN-on-sapphire, due to the use of high quality AlN buffer layer.

### EXAMPLE 3

### Molecular Beam Epitaxy of AlN Epilayers on Si Using a Nanowire-Based Hybrid Template: Path to Vertical Semiconductor Deep Ultraviolet Light Emitting Diodes

Deep ultraviolet (UV) light sources play a critical role in everyday life for a wide range of applications in disinfection and sterilization, bio-chemical sensing, UV curing in the production of any personal electronic devices, and so on. Some dominant technologies rely on mercury lamps, which are hazards to both the environment and human health. In this context, significant efforts have been devoted to the development of semiconductor deep UV light-emitting diodes (LEDs) based on aluminum gallium nitride (AlGaN) alloys, which are the materials of choice for semiconductor deep UV LEDs.

In general, there are two preferred ways to realize electrical injection for an LED device, one being vertical injection and the other being lateral injection. Comparing to lateral injection, vertical injection can offer a number of advantages such as uniform current injection, excellent scalability of the chip size, and simple packaging process. A uniform current injection can also be critical for laser devices. Nonetheless, vertical AlGaN deep UV LEDs remain to be a challenge in the field, and so far most demonstrations of AlGaN deep UV LEDs are through lateral injection. Two common ways of fabricating vertical LEDs are: 1) using conductive substrates, and 2) substrate removal and bonding to a second carrier wafer. These two approaches, however, can be difficult to implement for vertical AlGaN deep UV LEDs.

AlGaN deep UV LEDs can be on insulating sapphire substrate, precluding in situ vertical injection, whereas although n-SiC and n-GaN are conductive, they have a number of limitations. For example, the lattice mismatch between GaN and AlN is a known challenge. n-SiC (6H) faces a substrate cost penalty, in spite of its small lattice mismatch with AlN. More adversely, both n-SiC and n-GaN have a strong deep UV light absorption. As such, in both scenarios (insulating sapphire substrate and conductive n-GaN/n-Si substrates), substrate removal is necessary.

Laser lift-off (LLO) has been successful in some instances in the fabrication of InGaN visible color LEDs. However, the success may not be transferable to AlGaN deep UV LEDs, due to the need of AlN buffer layers for AlGaN deep UV LEDs. LLO of AlN is difficult due to the high melting point of AlN and the generation of Al during the LLO process, which can lead to crack and can be difficult to remove as well. This is in addition to a possible device structure degradation during LLO.

Another substrate choice is Si. Different from substrates mentioned above, Si can be removed easily by wet etching process. Moreover, Si substrate can be available at a large size at a low cost and thus may be more favorable for mass production. However, growing high quality AlGaN epilayers on Si remains a challenge. The large tensile stress in AlN and high-Al content AlGaN alloys due to the large lattice mismatch with Si (e.g., 19% for AlN) leads to poor material quality (e.g., cracks, poor surface morphology). To mitigate this challenge, various approaches, such as low-temperature (LT)/high-temperature (HT) AlN buffer layers, epitaxial lateral overgrowth (ELO)-AlN buffer layers, AlGaN superlattices (SLs), and graded AlGaN buffer layers, have been developed in an attempt to obtain high quality AlGaN device layers. These approaches, however, may require the use of complicated and time-consuming substrate patterning processes or growth processes. Moreover, several pm thick buffer layers are also required in order to have high quality device layers. The thick, insulating buffer layers used in these approaches typically leads to laterally injected AlGaN deep UV LEDs.

An alternative path for vertical AlGaN deep UV LEDs is to use nanowire structures. However, the fabrication of AlGaN nanowire deep UV LEDs is a remaining challenge. This can be due to the presence of gaps amongst nanowires. For example, due to the presence of gaps, certain planarization is required. Conventionally, this is done by polymer backfill. However, the commonly available polymers can absorb deep UV light strongly and degrade under deep UV light illumination.

In this example, a new approach is presented for vertical AlGaN deep UV LEDs using a thin AlN buffer layer formed on a nanowire-based hybrid template on Si substrate. Devices demonstrated in this example are in situ formed on Si substrate. As Si is a decent reflector in the deep UV range and highly electrical and thermal conductive, such a configuration can be a possible way of fabricating vertical AlGaN deep UV LEDs and can offer a potential benefit of direct integration to other electronic components on Si. More importantly, due to the thickness of the AlN buffer layer being very thin, it can be removed easily by chemical wet etching, compatible with the fabrication of vertical InGaN visible color LEDs on Si substrate. It can also allow for the achievement of ultimately high electrical and optical performance vertical AlGaN deep UV LEDs.

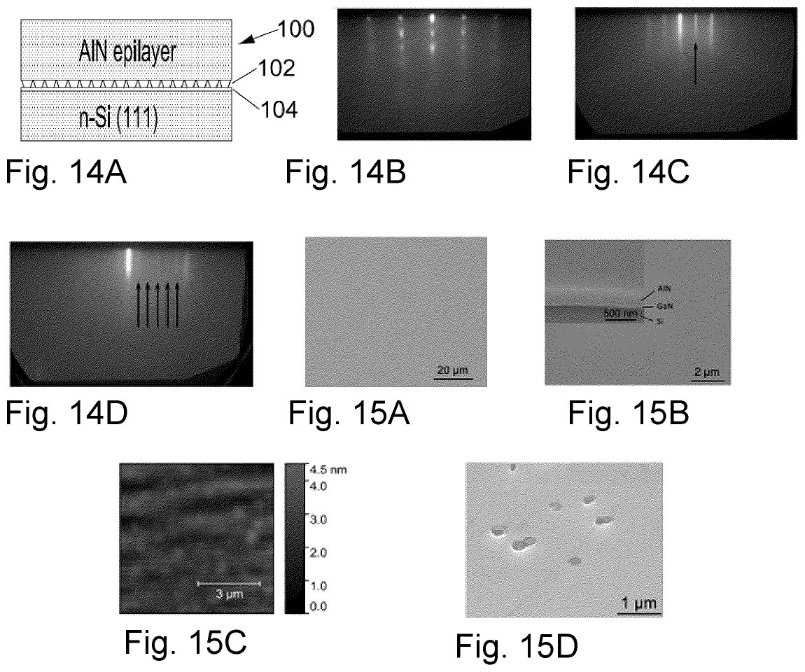

The molecular beam epitaxial (MBE) growth and characterization of the AlN epilayer that is used for the subsequent growth of AlGaN deep UV LED structures is described first. An example schematic of the structure 100 is shown in FIG. 14A, which utilizes a nanowire-based hybrid template, i.e., a thin (50-100 nm) GaN nanowire template 102 and a thin (1-2 nm) pre-nanowire AlN buffer layer 104. The purpose of using the thin pre-nanowire AlN buffer layer 104 was to relax any residual tensile stress from the Si substrate to the GaN nanowires. FIG. 14B shows the reflection high-energy electron diffraction (RHEED) pattern during the growth of the GaN nanowire template. Regularly arranged dots are seen, suggesting a 3-dimensional (3D) growth. This RHEED feature is different from the arcs as often observed from self-organized GaN nanowires, which indicates the improvement of the nanowire vertical alignment with respect to the substrate, due to the use of the thin pre-nanowire AlN buffer layer.

The start of the growth of the AlN epilayer led to a RHEED pattern transition from spotty to streaky. In this example, the AlN epilayer was grown in Al-rich condition, and the Al-rich growth condition was confirmed by the presence of a dynamic excess Al layer through the following observations: 1) the Al shutter open and close test, wherein the close of the Al shutter led to an increase of the RHEED intensity and the opening of the Al shutter led to an intensity decrease; and 2) the observation of the RHEED 2×6 reconstruction (FIG. 14C and FIG. 14D) during the growth (and occasionally during the cooling down as well), which is a signature of Al adlayer. Such a signature also reflects that the surface is Al-polar. In addition, the narrow, bright, and streaky RHEED pattern suggests a relatively smooth surface.

FIG. 15A shows the optical image of the as-grown wafer, an optically smooth surface can be seen. The surface of the as-grown wafer was further examined by scanning electron microscopy (SEM). The images were taken at a tilting angle of 45°. FIG. 15B shows an SEM image at a large scale, highlighting a very smooth surface. The inset of FIG. 15B shows a high-resolution SEM image, manifesting the cross section, with Si substrate, GaN nanowire template, and AlN epilayer clearly seen. The surface was further examined by atomic force microscopy (AFM). A typical AFM image is shown in FIG. 15C. In this study, a root-mean-square (RMS) roughness of as low as around 0.5 nm can be obtained, which is comparable to the typical metal-polar AlGaN thin films grown on sapphire and AlN-on-sapphire template.

To confirm the Al-polar polarity, potassium hydroxide (KOH) etching experiments were performed. In the experiments, 11.2 mol/L KOH solution was heated up to 70° C., and the sample was entirely placed in the solution, followed by de-ionized (DI) water cleaning. The SEM image of the surface after KOH etching is shown in FIG. 15D. It is seen that hexagonal pits, rather than hillocks, appeared after KOH etching, confirming that the surface is Al-polar. This Al-polar AlN epilayer can further enable metal-polar AlGaN epilayers grown on top. The benefit is, as the opposite side of the metal-polar surface is N-polar, which can be removed by KOH, it thus enables the removal of unwanted AlGaN epilayers (e.g., additional AlGaN buffer layers for material quality improvement), as well as the roughening of the surface through which the light comes out (for flip-chip devices). Indeed, the AlGaN epilayers to be described below are metal-polar as confirmed by KOH experiments.

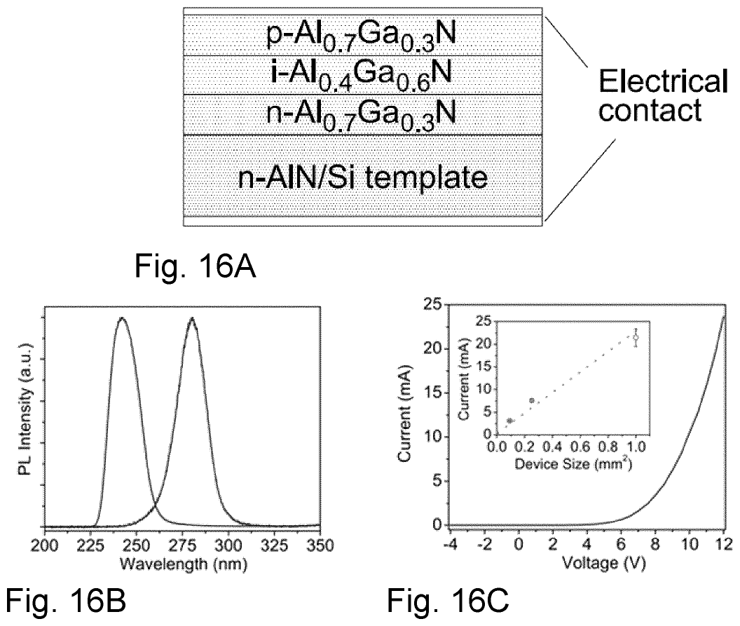

Vertical AlGaN deep UV LEDs are further demonstrated using such AlN epilayers on Si. The schematic of the device structure is shown in FIG. 16A, which consists of double heterojunctions (DHs) with an i-Al_{0.4}Ga_{0.6}N active region (˜15 nm) and p- and n-Al_{0.7}Ga_{0.3}N cladding layers (˜30 nm each). FIG. 16B shows the photoluminescence (PL) spectra measured at room temperature for the active region and cladding layers. It is seen that PL emission at around 240 nm and 280 nm are measured. Assuming the PL peak energy approximately to be the bandgap energy and a bowing factor to be 1, the Al contents in the active region and cladding layers were estimated to be ˜40% and ˜70%, respectively. It is also noted that only a single PL emission peak is seen for both the active region and cladding layers, suggesting a relatively uniform alloy composition. Moreover, no defect PL emission is seen in the UV range.

For device fabrication, no chemical etching was used to isolate devices with different sizes. The isolation was obtained by the limitation of the current spreading length in the vertical injection scheme. Calculations indicate that under an injection current density of 0.1 A/cm2, with the best reported p-AlGaN resistivity (Al content of 70%) and the largest ideality factor, as well as the present p-AlGaN layer thickness, the maximum current spreading length is on the order of tens of μm. Therefore, by placing p-contact with a separation on the order of several hundred pμ, devices can be naturally isolated.

The room-temperature I-V characteristics for a device with a size of 1 mm×1 mm under a continuous-wave (CW) biasing are shown in FIG. 16C. At a forward voltage of 9 V and 12 V, the forward current was 6 mA and 23 mA, respectively. This I-V characteristics appear to be improved compared to the previously reported laterally injected AlGaN thin film UV LEDs on Si at a similar operating wavelength. Moreover, the device size dependent current further shows a uniform current injection. Illustrated in the inset of FIG. 16C is a device size dependent current under a forward voltage of 12 V, and it is seen that the current increase is proportional to the device size increment, suggesting a uniform current injection.

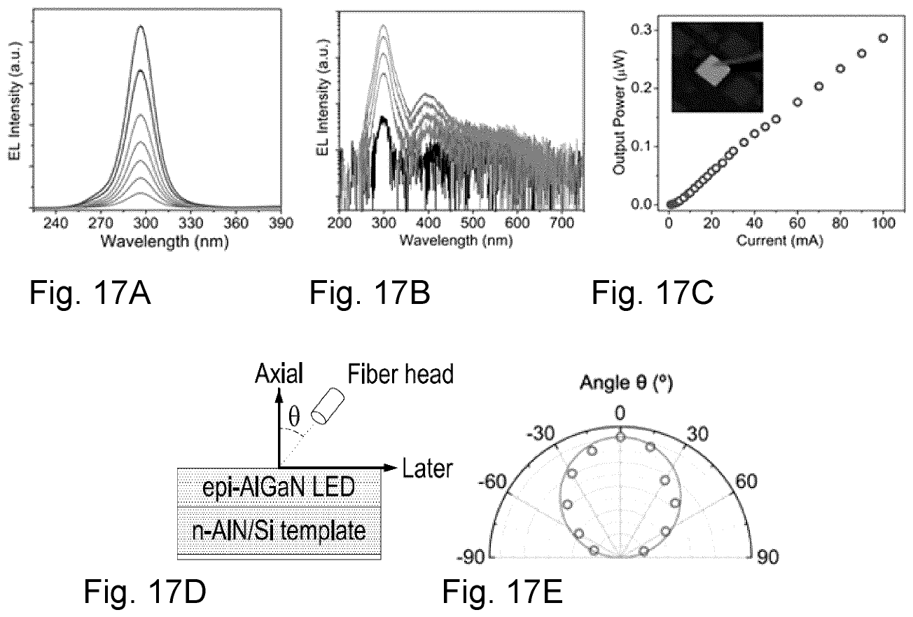

The electroluminescence (EL) spectra under different injection currents are shown in FIG. 17A. It is seen that the EL emission occurs at 298 nm. With the change of the injection current, no noticeable EL emission peak blueshift and full-width-at-half-maximum narrowing are observed, suggesting the absence of quantum confined stark effect. FIG. 17B shows the EL spectra measured with a UV-VIS spectrometer, intended to study the defect EL emission. It is seen that a parasitic EL emission at around 400 nm is seen, and the intensity is nearly two orders of magnitude lower than the main EL emission peak. FIG. 17C shows the light output power as a function of the injection current (device size: 1 mm×1 mm) under a CW biasing. A typical LED behavior is seen, i.e., the light output power increases nearly linearly with the injection current. Under an injection current of 100 mA, a light output power of 0.3 μW is measured. An optical image of the light emission is shown in the inset of FIG. 17C, wherein a bright and uniform emission can be seen. The emission pattern of such LEDs is also studied. In this regard, the optical fiber was tilted at various angles with respect to the axial direction (the growth direction) for the light detection, as illustrated in FIG. 17D. The emission pattern is shown in FIG. 17E by open circles. The ideal Lambertian emission pattern is also shown by the solid curve. It is seen that the device shows a near Lambertian pattern, suggesting the nature of surface emission.

Regarding molecular beam epitaxial growth, all the samples in this example were grown by radio-frequency plasma-assisted molecular beam epitaxy on n-Si (111) substrates. The substrates underwent standard solvent cleaning and in situ thermal outgassing, prior to the growth. The Al fluxes for the pre-nanowire AlN buffer layer and the AlN epilayer were 2×10⁻⁸ Torr and 5×10⁻⁸ Torr, respectively. For the AlGaN DH LED structure, the Al flux was in the range of 2.8 to 3.5×10⁻⁸ Torr. The Ga flux was around 1.4×10⁻⁷ Torr for all layers in this study. A nitrogen flow rate of 0.6 sccm was used for the GaN nanowire template, whereas for all the epilayers a nitrogen flow rate of 0.3 sccm was used. A substrate temperature in the range of 720 to 740° C. was used for the AlGaN epilayers; and for the AlN epilayers the substrate temperature was roughly 100° C. higher compared to AlGaN epilayers. The Mg doping concentration in the p-AlGaN layer was 1×10¹⁸ cm⁻³, estimated by the secondary-ion mass spectroscopy (SIMS, EAG lab).

In terms of photoluminescence experiments, a 213 nm pulsed laser with a pulse width of 7 ns was used to excite the sample. The emitted light from the sample top surface was collected by an optical fiber, which was further coupled to a deep UV spectrometer. In terms of device fabrication, conventional ohmic contact metal bilayer Ni (7 nm)/Au (7 nm) was used for p-contact, which was deposited by standard photolithography and metallization processes. Colloidal Ag conductive adhesive was used on the backside of n-Si substrate as the n-contact. In terms of device characterization, the electroluminescence emission was collected by an optical fiber from the device top surface, and both deep UV and UV-VIS spectrometers were used for the spectral analysis. The light output power was measured by a Si photodetector, which was placed roughly about 5 mm above the device top surface. The device was unpackaged.

In summary, this example has demonstrated vertical AlGaN deep UV LEDs on Si. Such devices can be made possible due to the use of a special AlN buffer layer that is formed with the assistance of a nanowire-based hybrid template. As Si is a decent reflector in the deep UV range, such vertical devices can offer a low-cost solution for vertical semiconductor deep UV LEDs and a potential benefit of in situ integration to other electronics on Si and are suitable for low-power applications. Further improvement on the electrical performance for such devices is expected by optimizing the electrical doping; and further improvement on the light output power can be expected by optimizing the p-contact and adopting more complicated device designs such as using quantum wells and electron blocking layers. More attractively, as the thickness of the AlN buffer layer is very thin, it can be removed easily using chemical wet etching (same for the nanowire template, as the sidewall of nanowires grown by MBE is N-polar), which allows the transfer of device structures grown on top to other carrier wafers for the achievement of vertical AlGaN deep UV LEDs with ultimately high electrical and optical performance. Therefore, this example enables a practical path for high performance vertical semiconductor deep UV LEDs

### EXAMPLE 4

### AlGaN Ultraviolet Light-Emitting Diodes on Si Using a Nanowire Sandwich Buffer Layer

Aluminum gallium nitride (AlGaN) deep ultraviolet (UV) light-emitting diodes (LEDs) are important photonic light sources that cover a wide range of applications, including disinfection, sensing, material identification. AlGaN deep UV LEDs at shorter wavelengths are even more attractive as they are considered human safe. Today, due to the lack of native substrate, AlGaN deep UV LED structures are grown on foreign substrates. Among various choices of substrates, silicon (Si) becomes attractive, not only because the advantage of Si as a substrate such as low substrate cost, readily availability of large substrate size, but more importantly, the successful in situ formation of AlGaN on Si offers a viable path for vertical semiconductor deep UV LEDs, which remains to be a challenge in the field.

Nonetheless, the development of AlGaN deep UV LEDs on Si experiences a severe lag compared to devices on other foreign substrates (e.g., sapphire). This is mainly due to the large lattice and thermal mismatches between AlGaN alloys and Si (e.g., 19% lattice mismatch between Si (111) and AlN), such that the epitaxy of AlGaN deep UV LED structures on Si is a challenge. The tensile stress from Si substrate often leads to poor material quality such as cracks and large dislocation densities.

The main approaches, hitherto, used to improve the quality of AlGaN epilayers on Si include using epitaxial lateral overgrowth (ELO)-AlN buffer layers, AlGaN/AlN superlattices, and graded AlGaN buffer layers. Even with these efforts, there are only limited reports of AlGaN deep UV LEDs on Si. Furthermore, the shortest device operation wavelength reported so far has been limited to 257 nm. Moreover, the thick and insulating buffer layers used in these approaches prevent devices through vertical injection, regardless of the device operation wavelength. In addition, thick and complex buffer layers, as well as substrate patterning, used in these approaches increase growth complexity and time and dollar costs.

An alternative path for AlGaN deep UV LEDs on Si explored so far is using nanowire structures. However, the fabrication of AlGaN nanowire deep UV LEDs remains challenging. It is ideal to have an AlGaN deep UV LED technology on Si that combines the advantage of nanowire structures (e.g., better stress relaxation) and thin film devices (e.g., manufacturing compatible device fabrication process). In this example, such an AlGaN deep UV LED technology is shown on Si. Devices emitting down to 247 nm are demonstrated. Furthermore, different from the previously reported devices on Si, devices demonstrated in this work are through vertical injection. Moreover, compared to the previously reported laterally injected devices, the electrical performance is improved.

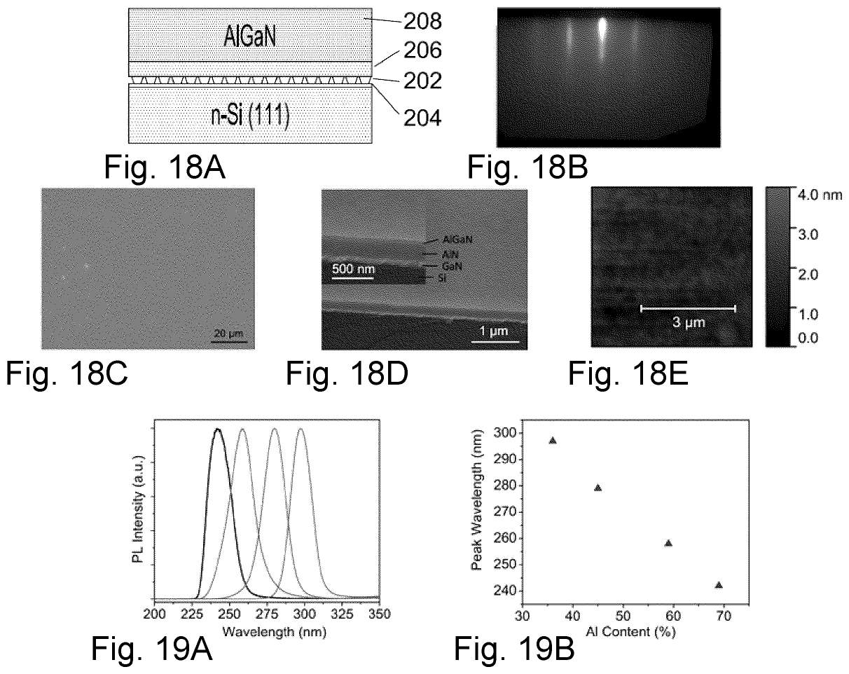

Such AlGaN deep UV LEDs exploit AlGaN epilayers grown on a nanowire sandwich buffer layer. The schematic of the growth of the AlGaN epilayer is shown in FIG. 18A, which involves the usage of a thin nanowire layer 202, sandwiched between a thin pre-nanowire AlN layer 204, and a post-nanowire AlN layer 206, prior to the growth of the AlGaN epilayer 208. The thin pre-nanowire AlN layer 204 is to relax any residual tensile stress on the nanowire layer from the Si substrate. Radio-frequency plasma-assisted molecular beam epitaxy was used for the materials growth. The growth condition of the thin pre-nanowire AlN layer followed an Al-first approach, as described elsewhere. The GaN nanowire layer was grown in N-rich condition, whereas both the post-nanowire AlN layer and AlGaN epilayer were grown in metal-rich conditions. The growth condition of AlGaN epilayers included an Al flux of 2.5×10⁻⁸ to 3.5×10⁻⁸ Torr, a Ga flux of 1.2×10⁻⁷ to 1.4×10⁻⁷ Torr, and a nitrogen flow rate of 0.3 standard cubic center meter (sccm). The substrate temperature was varied from 720° C. to 740° C. The temperature was calibrated using the Si substrate reflection high-energy electron diffraction (RHEED) 7×7 reconstruction.

The metal-rich conditions in this study are confirmed by the RHEED intensity change when the metal shutter open/close test was performed. FIG. 18B shows the typical RHEED pattern during the growth of AlGaN epilayers. Streaky RHEED pattern was observed throughout the growth, suggesting a relatively smooth surface. FIG. 18C shows an optical image of the surface of the as-grown AlGaN epilayer. It is seen that the surface is optically smooth. FIG. 18D shows the scanning electron microscope (SEM) image taken at a tiling angle of 45°. A smooth surface can be seen. The image contrast at the cross-section (inset of FIG. 18D) manifests the GaN nanowire layer, top AlN layer, and AlGaN epilayer. Atomic force microscopy (AFM) was further carried out to examine the surface of the as-grown AlGaN epilayer. FIG. 18E shows a typical AFM image. A rms roughness of as low as 0.7 nm was obtained in this study. The as grown surface was further etched by potassium hydroxide (KOH, 11.2 mol/L at 70° C.). Hexagonal-shaped pits, rather than hillocks, were observed, suggesting a metal-polar surface.

AlGaN epilayers with different Al contents were further investigated by photoluminescence (PL) experiments. In the PL experiments, the samples were excited by a 213 nm pulsed laser. The emitted light was collected from the sample top surface through an optical fiber, which was further coupled to a deep UV spectrometer. FIG. 19A shows the room-temperature PL spectra. It is seen that PL emission from 242 nm to 300 nm is measured. The Al content is further estimated using the room-temperature PL peak wavelength λ, with the equation E_{PL}(x)=hc/λ≈E_{g} (AlGaN)=(1−x)E_{g} (GaN)+xE_{g}(AlN)−bx(1−x), where x is the Al content, h is the Planck's constant, c is the speed of light, E_{g} is the bandgap energy, and b is the bowing parameter. Bandgap energies E_{g} of 3.4 eV and 6.2 eV (for GaN and AlN, respectively) and bowing parameter b of 1 eV were used in the estimation. Shown in FIG. 19B is the PL peak wavelength vs. the Al content for various samples. It is seen that Al contents in the range of ˜35% to 70% are obtained. It is further noted that, only a single PL emission peak is present, suggesting a relatively uniform compositional distribution in the present AlGaN epilayers. Estimation of the room-temperature internal quantum efficiency (IQE) calculated using the ABC model further indicated that, for such AlGaN epilayers, IQEs of around 30-40% can be obtained at low excitation conditions.

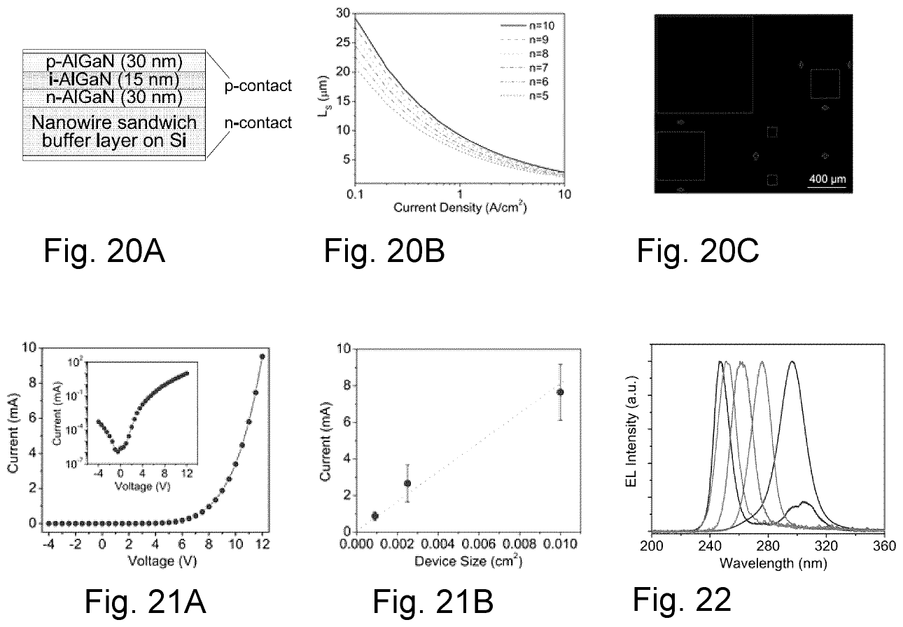

Vertical deep UV LEDs using such AlGaN epilayers are further demonstrated. FIG. 20A shows the device schematic, which consists of the nanowire sandwich buffer layer on Si and AlGaN p-i-n double heterojunctions (DHs). The thicknesses for the active region and cladding layers were 15 and 30 nm, respectively. The Al content in the AlGaN cladding layers was maintained at around 70%, whereas the Al content in the active region was varied in order to obtain different light emission wavelengths. The Mg doping concentration for p-AlGaN cladding layer was 5×1018 cm, estimated from the secondary-ion mass spectroscopy (SIMS), performed at EAG Labs. In the present study, the Mg doping neither degrades the surface quality of the epilayer nor incurs polarity inversion due to the moderate doping level.

Conventional ohmic contact bilayer Ni (7 nm)/Au (7 nm) was used as the p-contact, which was deposited by e-beam evaporator, following standard photolithography and patterning process. Ag colloidal adhesive was used as the n-contact on the back side of the n-Si substrate. In the device fabrication process, the limitation of the current spreading length in the vertical injection scheme was used to define and isolate devices with different sizes. The current spreading length Lₛ was estimated by Lₛ=√(tnkT/epJ₀), where t is the thickness of the current spreading layer (in this work, it is the thickness of the p-AlGaN layer), n is the ideality factor, p is the resistivity of the p-AlGaN layer, and J₀ is the forward current density. Additionally, k, T, and e stand for the Boltzmann constant, temperature, and unit charge, respectively. A wide range of ideality factors of group-III nitride LEDs from previous reports were considered. The resistivity of the p-AlGaN layer (with an Al content of around 70%) was taken from the best reported so far (assuming that the p-layer is inferior to the state-of-the-art number). FIG. 20B shows the calculated current spreading length as a function of the forward current density. It is seen that, the maximum current spreading length is less than 30 μm. As such, if the separation of the p-contact is on the order of several hundred μm, the limited current spreading in the vertical injection scheme can naturally isolate different devices. FIG. 20C shows a portion of the mask design for devices with different sizes. The squares denote p-contact, with a separation of around 300 pm.

Electrical performance of such LED devices was further tested. In this regard, the current-voltage (I-V) characteristics of devices with different sizes were measured by Keithley 2400 source meter under a continuous-wave (CW) biasing. FIG. 21A and its inset show the typical I-V characteristics of a device with a size of 1 mm×1 mm in the linear and semi-logarithmic scale, respectively. The forward current at 9 V and 12 V were around 2 mA and 10 mA, respectively. This electrical performance is improved comparable to the previously demonstrated laterally injected AlGaN UV LEDs on Si. Nonetheless, the electrical performance of the present devices has remained poor. Improved electrical performance is expected by further optimizing the electrical doping, as well as removing the Si substrate and the nanowire sandwich buffer layer.

Nearly uniform current injection is also found in the present devices. FIG. 21B shows the forward current at a forward voltage of 12 V for devices with different sizes. It is seen that the increment of the current is proportional to the device size increase, indicating a uniform current injection.

The light emission of such LED devices was studied in the end. In this case, the electroluminescence (EL) spectra were taken from the device top surface with an optical fiber, which was further coupled to a deep UV spectrometer. FIG. 22 shows the room temperature EL spectra. It is seen that devices emitting from 247 nm to 298 nm are obtained. The presence of the p-AlGaN related EL emission peak for devices emitting at 247 nm could be ascribed to the reduced carrier confinement in the active region, due to the increase of the Al content in the active region while keeping the Al content in the cladding layer similar.

For the present vertical AlGaN deep UV LEDs, the light output power has remained low, on the order of several hundred nano-watt. Besides the lack of complicated device designs such as multiple quantum wells (QWs) and electron blocking layers (EBLs), another reason is the light blocking by p-contact. This issue can be solved by using conventional dry etching to isolate devices and optimizing p-contact design. Moreover, the light output power can also be improved by using graphene electrode. Separately, by removing Si substrate and the nanowire sandwich buffer layer and transferring device structures to reflectors could also improve the light output power.

In conclusion, in this example a new approach for the epitaxy of AlGaN epilayers on Si substrate was reported. The approach involves using a sandwich buffer layer combining nanowires and AlN layers. AlGaN epilayers with Al contents varying from —35% to 70% are obtained. Both SEM and AFM experiments indicate that such AlGaN epilayers have a smooth surface, with a rms roughness of as low as 0.7 nm. Vertical AlGaN deep UV LEDs down to 247 nm are further demonstrated. Studies on the I-V characteristics suggest a uniform current injection and improved electrical performance compared to the previously reported laterally injected devices.

Today, despite of the advantages of vertical LEDs, such as uniform current in the device active region, easy to scale up, and reduced device fabrication complexity, AlGaN deep UV LEDs are mainly through lateral injection. This work exhibits the first AlGaN epilayer based devices with vertical current injection on Si. 247 nm also represents the shortest wavelength for devices made with AlGaN epilayers on Si. It is further noted that, although Si is highly absorbing in the visible, it is a decent reflector in the deep UV range. Therefore, devices demonstrated in this work could be a possible format of vertical AlGaN deep UV LEDs. Moreover, such AlGaN epilayers can be transferred easily to other substrates by removing both the Si substrate and the nanowire sandwich buffer layer through chemical wet etching, which could allow for the achievement of vertical AlGaN deep UV LEDs with ultimately high electrical and optical performance.

### EXAMPLE 5

### Molecular Beam Epitaxy of Aln Epilayers Using a Nanowire Template on Si With Controlled Surface Morphology and Polarity

Aluminum nitride (AlN) is an important compound semiconductor for electronic and photonic devices, not only because of its wide range applications to very short wavelength light emitting (down to 207 nm at room temperature), high-electron mobility transistors, and field-emission, but also because AlN is an important buffer layer for group-III nitride electronic and photonic devices on any substrates (e.g., sapphire, Si) for stress management. On the other hand, given the dominant role of Si in modern electronic industries, plus a number of advantages of Si substrate such as the readily availability of large scale wafers at a low cost, the easy removal for flip-chip light emitting diodes (LEDs), it is appealing to develop AlN on Si technology.

Nonetheless, owing to the large lattice and thermal mismatches between AlN and Si, obtaining high-quality AlN on Si is not an easy task. Different from the epitaxy of GaN on Si, wherein AlN buffer layer can be used to compensate the tensile stress from the Si substrate, such a solution is not available for AlN. As a consequence, there are not so many effective ways of reducing the tensile stress from Si for AlN. The existing solutions include using pulsed epitaxial growth method, silicon-on-insulator (SOI) wafers, Si substrates with different orientations, and epitaxial lateral overgrowth (ELO) on patterned substrates. Hitherto, ELO on pattern Si substrates seems to be the most promising approach; however, such an approach overall requires complicated patterning process, followed by long growth duration, which raises the manufacturing cost, making it time- and cost-ineffective. The need of thick buffer layers of several pm also makes their removal difficult for the subsequent device processing, e.g., the fabrication of flip-chip vertical AlGaN deep ultraviolet (UV) LEDs.

On the other hand, as the surface of group-III nitride semiconductors in general play a vital role in their device applications, e.g., whether the surface is terminated with metal species or nitrogen will lead to different electrical and optical properties, smoother surface is also favourable for laser devices due to lower optical loss, it is pivotal to understand and control the surface properties of AlN epilayers grown on Si substrate.

In this example, a new path of growing AlN epilayers on Si substrate with controlled surface morphology and polarity is investigated, using a thin nanowire template. In the past, nanowires have drawn a significant attention due to their unique geometry as well as the associated novel electrical and optical properties for applications in both electronics and photonics. Moreover, in the light of better stress relaxation in nanowire structures compared to planar counterparts, nanowires can also be potentially used to obtained epilayers through a coalescence process. The existing studies, however, are mainly limited to GaN epilayers, due to the challenge in the growth of AlN epilayers. In this example, there is described AlN epilayers with controlled surface morphology and polarity using a thin nanowire template on Si substrate by molecular beam epitaxy (MBE), and further elucidate the detailed growth conditions dependent surface properties. Besides obtaining a highly smooth surface, a simple way of controlling the polarity of such AlN epilayers is shown, which is meaningful for their applications to both electronic and photonic devices, e.g., the N-polar AlN epilayers could help to dress the notorious electron overflow issue in AlGaN deep UV LEDs, and the Al-polar AlN epilayers could help to the realization of vertical AlGaN deep UV LEDs.

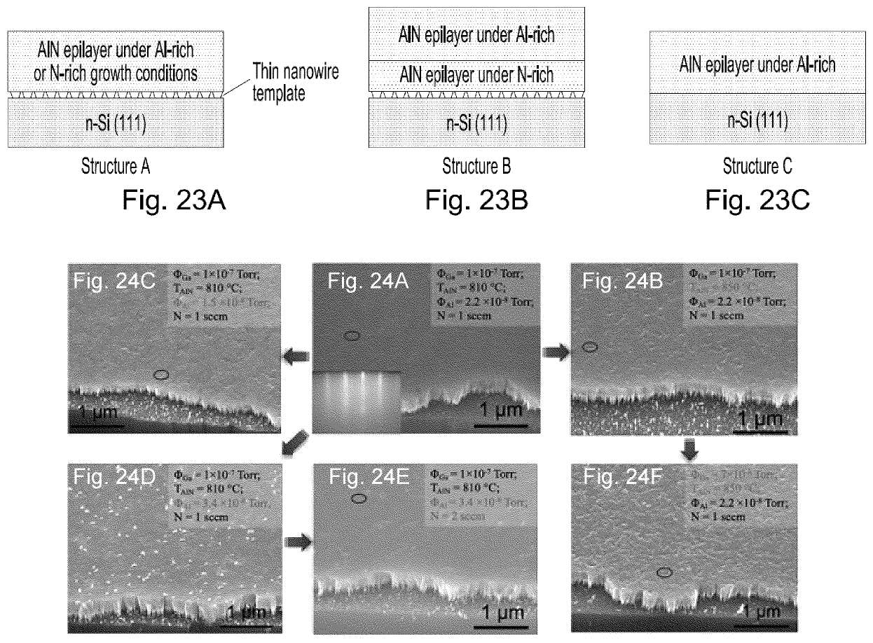

In this example, all the samples were grown by radio-frequency plasma-assisted MBE on n-Si (111) substrates. FIG. 23A describes the typical structure (Structure A) used in this study about the growth of the AlN epilayers. The AlN epilayer growth starts with a thin GaN nanowire template (50-100 nm). Before the GaN nanowire template growth, a thin AlN buffer layer (1-2 nm) was used in some growth runs (to be discussed along with the results). The thin AlN buffer layer in this case was grown by an Al-first approach. All GaN nanowire templates were grown in N-rich conditions, whereas the AlN epilayers on top were grown either in N-rich or Al-rich conditions (details are described along with the results). Structures B (FIG. 23B) and C (FIG. 23C) are test structures and are used to provide a comprehensive understanding of obtaining Al-polar AlN epilayers in this study. Reflection high-energy electron diffraction (RHEED) was used to monitor the growth in situ.

To study the surface morphology, scanning electron microscopy (SEM) images were taken, at a tilting angle of 45°. Potassium hydroxide (KOH) etching was used to assess the polarity of the epilayers, in addition to RHEED. Two etching conditions, mild (3 mol/L at room temperature) and harsh (11.2 mol/L at 70° C.), were used. The etching time will be discussed along with the results.

The MBE growth and characterization of AlN epilayers under N-rich condition is first investigated. In this case, no thin AlN buffer layers were used before the growth of the GaN nanowire template. The growth condition of the GaN nanowire template included a substrate temperature of 720° C., a nitrogen flow rate of 0.6 sccm, and a Ga flux (ΦGa) of around 1×10⁻⁷ Torr. FIG. 24A shows the SEM image of the AlN epilayer grown with an Al flux (ΦAl) of 2.2×10⁻⁸ Torr, a nitrogen flow rate of 1 sccm, and a growth temperature (TAlN) of 810° C. It is seen that a relatively smooth surface was obtained. The inset of FIG. 24A shows the RHEED pattern during the growth of the AlN epilayer. Streaky RHEED is seen, suggesting a relatively smooth surface.

The effect of the growth temperature on the surface morphology of the AlN epilayers is further investigated. In this case, the growth condition of the GaN nanowire template was fixed. FIG. 24B shows the SEM of the AlN epilayer grown with an increased temperature (TAlN of 850° C.), with the rest parameters remained the same. In this case, a significant number of pits are seen, with an estimated density of 2.5×10⁹ cm⁻². This could be explained by the following: due to the increased growth temperature, Al migration is enhanced such that the coalescence process is impeded, and the incomplete or partial coalescence leads to the formation of pits at the surface.

The effect of the Al/N ratio on the surface morphology is investigated next. Shown in FIG. 24C, by reducing ΦAl from 2.2×10⁻⁹ Torr to 1.5×10⁻⁸ Torr, while keeping the rest of the growth parameters to be the same, the surface also becomes rough, with a noticeable increased number of pits at the surface. The estimated pits density is 1.2×10⁹ cm⁻². This could indicate that a lower Al flux in the N-rich condition at TAlN of 810° C. may not be favourable for 2-dimensional (2D) growth or coalescence. By increasing the Al flux from 2.2×10⁻⁸ Torr to 3.4×10⁻⁸ Torr, on the other hand, leads to the presence of nanoclusters at the surface with a significantly reduced pits density, as illustrated in FIG. 24D. The estimated density of the clusters is 1×10⁹ cm⁻². This suggests that, the change in Al/N ratio affects the surface drastically, and the optimized Al flux at a nitrogen flow rate of 1 sccm and TAlN of 810° C. is around 2.2×10⁻⁸ Torr. However, although increasing ΦAl leads to nanoclusters at the surface (for TAlN of 810° C. and nitrogen flow rate of 1 sccm), further increasing the nitrogen flow rate to 2 sccm with the Al flux unchanged can restore a relatively smooth surface, as shown in FIG. 24E.

The role of the GaN nanowire template on the surface quality of the AlN epilayer atop is investigated as well. In this case, the growth condition of the top AlN epilayer was kept the same as the one used in FIG. 24B, but reduced the Ga flux from 1×10⁻⁷ Torr to 7×10⁻⁸ Torr in the growth of the GaN nanowire template. Shown in FIG. 24F, the top surface exhibits a nearly incomplete coalescence, with noticeable columnar features. This can be understood by the following: the reduced Ga flux results in a decrease in both the diameter and height of the GaN nanowires, which is not favorable for the subsequent coalescence of AlN, leading to a poor surface morphology. In these examples, the RHEED pattern along <1120 > direction corresponds to the one shown at inset of FIG. 24A. The growth parameters, including Ga flux (ΦGa) in the GaN nanowire template, growth temperature (TAlN), Al flux (ΦAl) and nitrogen flow rate (N) in the AlN layer are labeled in each figure. The pits density in each sample is: 4×10⁸ cm⁻² in FIG. 24A; 2.5×10⁹ cm⁻² in FIG. 24B; 1.2×10⁹ cm⁻² in FIG. 24C; 1×10⁹ cm⁻² (density of nanoclusters) in FIG. 24D; 2×10 ⁸ cm⁻² in FIG. 24E; >5×10⁹ cm⁻² (due to incomplete coalescence) in FIG. 24F.

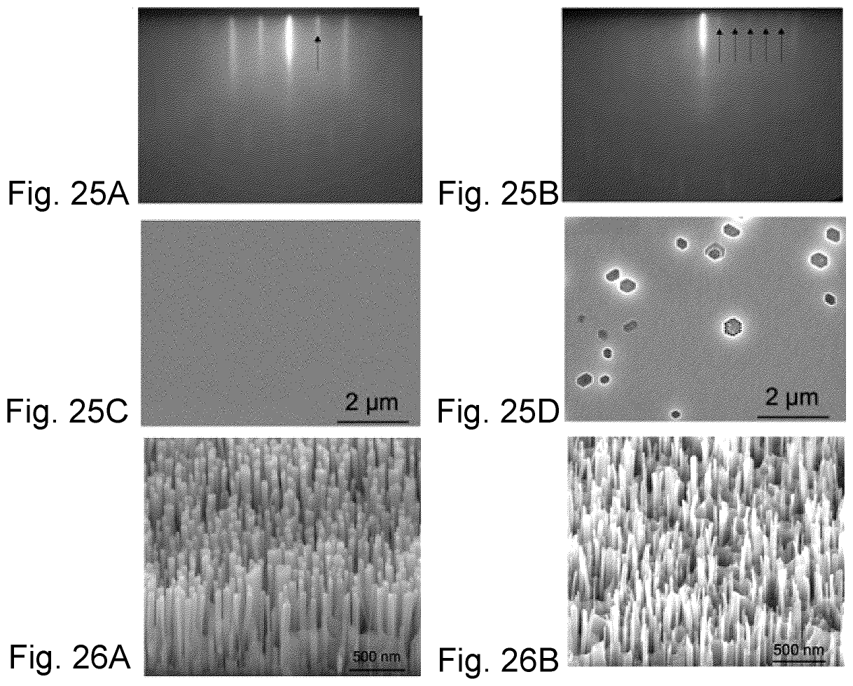

Turning now to Al-rich growth conditions. In this case, a pre-nanowire thin AlN buffer layer was used, which was grown by Al-first approach with an Al flux of around 2×10⁻⁸ Torr. The growth condition of the top AlN epilayers included a growth temperature of 860° C., an Al flux of 5×10⁻⁸ Torr, and a nitrogen flow rate of 0.3 sccm. The Al-rich condition was confirmed by the RHEED intensity change in the Al shutter open/close test, as well as the 2×6 RHEED reconstruction (FIGS. 25A and 25B)—a reflection of the presence of Al adlayer. Moreover, the RHEED patterns of the AlN epilayers grown in the Al-rich condition are more streaky and bright compared to the RHEED patterns of the AlN epilayers grown in N-rich conditions, suggesting an improved surface morphology. Shown in FIG. 25C is the SEM image showing the surface of the AlN epilayers grown in the Al-rich condition, and it is seen that the surface is much smoother than the AlN epilayers grown in N-rich conditions (e.g., see FIG. 24A).

Atomic force microscopy (AFM) scans further indicate that such Al-polar AlN epilayers can have a root-mean-square (rms) surface roughness of as low as 0.5 nm, on par with the typical rms roughness of the metal-polar AlGaN epilayers grown on sapphire or bulk AlN substrates. On the other hand, however, the rms roughness of the N-polar AlN epilayers in the present study is around 2 nm, significantly rougher compared to the Al-polar AlN epilayers. However, such N-polar AlN epilayers are grown in N-rich conditions, and compare to the requirement of a precise control on the excess metal species in metal-rich condition, the growth condition is more relaxed in N-rich condition, favorable for repeatable growth. The rms roughness here is also within the range of rms values of group-III nitride epilayers grown in N-rich condition by MBE.

The 2×6 RHEED reconstruction observed during the growth of the AlN epilayers in Al-rich condition also indicates that the surface is Al-polar. The Al-polar surface is further confirmed by KOH etching experiments. FIG. 25D shows the SEM image of the surface of the Al-polar AlN epilayers after KOH etching in the harsh condition for 30 minutes (mild condition does not etch such AlN epilayers). Hexagonal-shaped pits, rather than hillocks, are seen, confirming that the surface is indeed Al-polar, consistent with the RHEED pattern reconstruction. This is in contrast to the AlN epilayers grown in N-rich conditions, which are found to be N-polar from previous examples.

In the following, the mechanism of obtaining Al-polar AlN epilayers using N-polar nanowire template is studied. It is well-known that GaN nanowires grown on Si, with or without thin AlN buffer layers are predominantly N-polar; therefore, obtaining Al-polar AlN epilayers may indicate a polarity inversion. To confirm the polarity inversion, the polarity of such GaN nanowires was examined. Shown in FIGS. 26A and 26B are the SEM images of the GaN nanowires before and after 15 seconds KOH etching in the mild condition. It is seen that the GaN nanowires are noticeably thinner and shorter after the etching, suggesting that both the sidewall and the top surface of the GaN nanowires are N-polar. This therefore confirms the polarity inversion.

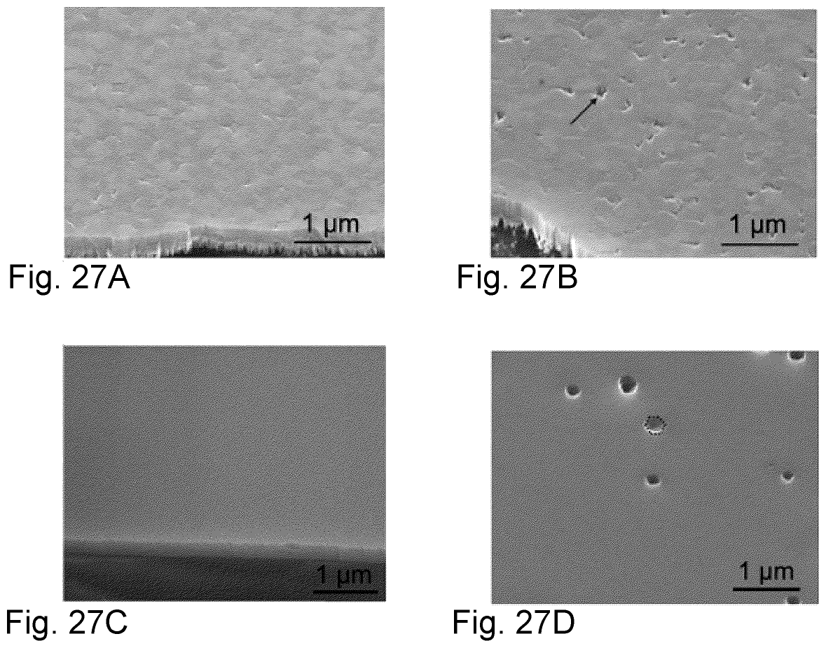

The polarity inversion could be related to the coalescence process or simply due to the use of the Al-rich growth condition. To further examine the cause, the growth of AlN epilayers was performed in two steps (Structure B in FIG. 23B). The first step is under the N-rich condition with TAlN, ΦAl, and the nitrogen flow rate of 810° C., 2.2×10⁻⁸ Torr, and 1 sccm, respectively. The second step is under the Al-rich growth condition with TAlN, ΦAl, and the nitrogen flow rate of 870° C., 5×10⁻⁸ Torr, and 0.3 sccm, respectively. After the two-step growth, the sample was etched by KOH. FIGS. 27A and 27B show the SEM images of the surface before and after KOH etching in the harsh condition for 15 seconds. It is seen that compared to the as-grown surface, pits, rather than hillocks, are seen, suggesting that the surface is Al-polar. These experiments therefore indicate that the polarity inversion is likely due to the use of the Al-rich growth condition.

To further test this hypothesis, the direct AlN epilayer growth on Si substrate (Structure C in FIG. 23C) was performed in the same Al-rich condition as used above. The SEM image of the as-grown surface is shown in FIG. 27C; a smooth surface can be seen. KOH etching experiments were then performed. FIG. 27D shows the SEM image of the surface after 1 minute KOH etching in the harsh condition. Hexagonal shaped pits are clearly seen, indicating that the surface is Al-polar. As such, this example suggests that the polarity inversion is due to the use of the Al-rich growth condition.

Polarity inversion in AlN has been investigated in the past. It is found that the polarity inversion is dominated by growth kinetics and strongly dependent on the Al/N ratio, as well as the initial nucleation temperature. The presence of Al adlayer in the growth front can lead to a transition from N-polar to Al-polar. As indicated by the RHEED pattern reconstruction in this example, Al adlayer is present, which thus could lead to the polarity inversion from N-polar to Al-polar. Such a polarity inversion could be favourable for the removal of the AlN buffer layer for the fabrication of flip-chip vertical AlGaN deep UV LEDs, as the opposite side of the top surface is N-polar, and thus can be readily etched by KOH.

There is presented a detailed study on the MBE growth and characterization of a special kind of AlN epilayers on Si substrate, with a focus on the surface properties. For the AlN epilayers grown under N-rich growth conditions, the Al/N ratio, growth temperature, as well as the growth condition of the GaN nanowire template all become rather important to control the surface morphology. Under the Al-rich growth condition, an improved surface morphology is seen, and the surface is found to be Al-polar, in contrast to the AlN epilayers grown in N-rich conditions. The Al-polar AlN epilayers are obtained on N-polar nanowire template, which thus suggests a polarity inversion. Detailed analysis further indicates that such a polarity inversion is attributed to the presence of Al adlayer due to the use of the Al-rich growth condition. Hitherto, AlN on Si technology has remained immature, this study demonstrates a new avenue of obtaining AlN on Si substrate, with controlled surface morphology. Moreover, the polarity of such special AlN epilayers can also be simply controlled by using either N-rich growth conditions (for N-polar AlN epilayers) or Al-rich growth conditions (for Al-polar AlN epilayers).

### EXAMPLE 6

### AlGaN Nanowire Deep Ultraviolet Light Emitting Diodes with Graphene Electrode

Surface-emitting aluminum gallium nitride (AlGaN) deep ultraviolet (UV) light emitting diodes (LEDs), i.e., with emission wavelengths shorter than 300 nm, are extremely important for a wide range of applications such as material identification, bio-chemical sensing, medical treatment, UV curing, and surface sterilization. Moreover, even shorter wavelengths such as those close to 200 nm are found to be human safe, due to the ultrashort penetration depth to the healthy human cells. As such, there is a great interest of developing short-wavelength surface-emitting AlGaN deep UV LEDs. However, short-wavelength surface-emitting AlGaN deep UV LEDs face a number of challenges, such as the lattice and thermal mismatches with the commonly used substrates and the optical polarization change from the transverse electric (TE) to the transverse magnetic (TM) as the Al content increases, which is required to obtain shorter wavelengths.

Comparing with surface-emitting LEDs through lateral injection, vertical LEDs offer many advantages such as uniform current injection, simplified fabrication process. Despite of these advantages, AlGaN deep UV LEDs demonstrated today are mainly through lateral injection. This is largely because the commonly used substrates such as sapphire or AlN-on-sapphire template are insulating, as well as the difficulty and complexity in the laser lift-off of AlN buffer layers.

Hitherto, short-wavelength surface-emitting vertical AlGaN deep UV LEDs are primarily employing nanowire structures, as high quality AlN and AlGaN nanowires can be formed on highly conductive n-type Si substrate. Using such an approach, surface-emitting vertical AlGaN deep UV LEDs down to 207 nm have been demonstrated. In such devices, conventional metal contacts (e.g., Ni/Au, Ti/Au) are used for the top surface electrical contact, which blocks the deep UV light emission severely. Further improvement of the device performance requires the use of an electrical contact which has greater transparency to the deep UV light than conventional metal contacts.

Among various choices, graphene is an attractive option, due to its excellent electrical conduction and high optical transmission in the whole UV range. So far, the two main approaches of applying graphene to group-III nitride LEDs are: 1) using a transfer process after the epitaxial growth of the device structure. Using this approach, InGaN blue LEDs with graphene electrode have been demonstrated; and 2) using graphene as an intermediate layer for the subsequent epitaxial growth of the device structure. Using this method, GaN-based vertical UV LEDs emitting down to 350 nm have been demonstrated; however, these devices suffer from graphene degradation introduced in the epitaxial growth process of the device structure. In addition, Yamada et al. showed graphene growth directly on the epitaxially grown device structure, and demonstrated devices in the visible spectral range. In spite of these studies, much less is known about applying graphene to AlGaN nanowire deep UV LEDs. In fact, there have been no experimental demonstrations of any kind of AlGaN deep UV LEDs using graphene as the top electrode.

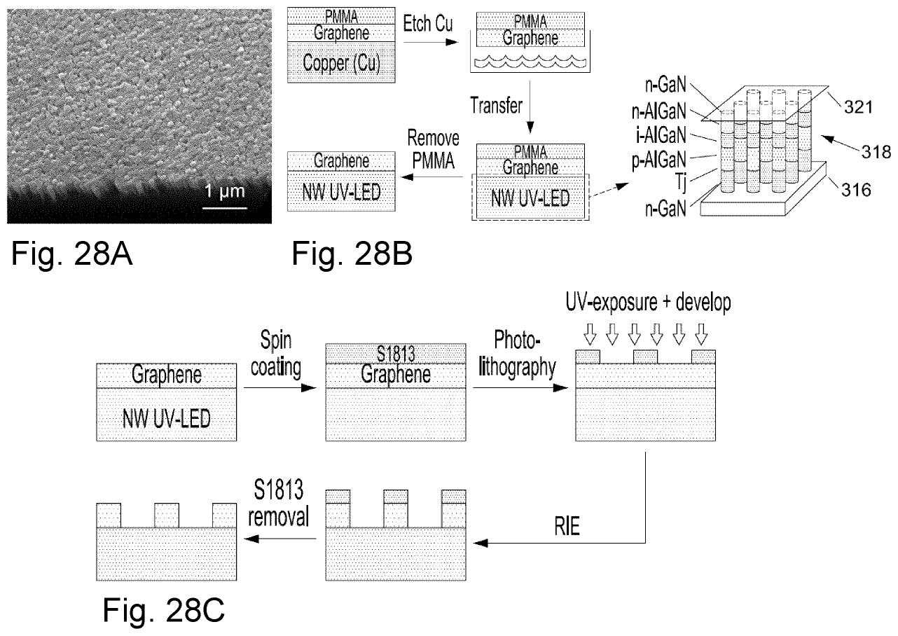

The substrate that can be used for the device can have a semiconductor wafer 316, an intermediate nanowire layer 318 having a plurality of nanowires each having in succession a base portion mounted to the semiconductor wafer 316 (in this case a Si substrate), an elongated body portion extending away from the semiconductor wafer, and a tip portion, and a graphene electrode 321 being made integral to the tip portions of the plurality of nanowires, such as shown in FIGS. 28A and 28B. In this example, there is provided a detailed experimental study on surface-emitting vertical AlGaN nanowire deep UV LEDs with graphene electrode. Devices emitting down to 240 nm are demonstrated. It is further found that, compared to using metal contact, graphene electrode improves both the light output power and external quantum efficiency (EQE) at low injection currents. Nonetheless, the devices with graphene electrode show a more severe efficiency droop, compared to devices with metal contact. This can be attributed mainly to the large contact resistance of devices with graphene electrode, which is presumably ascribed to the poor adhesion of graphene to the nanowire top surface due to the non-uniform height of the nanowires formed through a self-organization process. Using nanowires by selective area epitaxy, could possibly alleviate this issue. Nonetheless, uniform light emission is observed, suggesting that even in this case, graphene electrode can still spread the current relatively well.

AlGaN nanowire device structures in this example are grown by plasma-assisted molecular beam epitaxy (PAMBE) on highly conductive n-Si substrate in nitrogen rich conditions. Prior to the MBE growth, the Si wafer was cleaned by isopropanol alcohol (IPA) and etched by hydrofluoric (HF) acid, and then thermally outgassed in the MBE chamber in situ. Atypical scanning electron microscope (SEM) image of AlGaN nanowires is shown in FIG. 28A. It is seen that relatively uniform nanowires are formed. The layer-by-layer structure in each individual nanowire is shown in the inset of FIG. 28B. From the bottom to the top, it consists of n-GaN nanowire template, a n+-GaNip+-AlGaN tunnel junction, AlGaN nanowire double-heterojunctions (DHs), and a heavily doped n-GaN contact layer. The growth conditions for the AlGaN nanowire DHs included a substrate temperature in the range of 850-890° C., Al fluxes in the range of 1-2×10⁻⁸ Torr, Ga fluxes of 0.8-1.5×10⁻⁸ Torr, and a nitrogen flow rate of 0.6 sccm. A lower substrate temperature of 630° C. was used for the growth of the tunnel junction, and the Al content in the p+-AlGaN was around 20%, estimated by photoluminescence experiments. P-type and n-type doping concentrations were similar to the previous report.

The graphene was then transferred to the grown wafer, followed by patterning, in order to fabricate devices with different sizes. The graphene transfer process is schematically shown in FIG. 28B. First, commercial monolayer graphene on copper (Cu) foil coated with polymethyl methacrylate (PMMA) was etched using a chloride-based etchant, followed by rinsing with deionized (DI) water to remove any residues and transferring the graphene/PMMA to the top of the nanowire device structure. The sample with graphene/PMMA was then air-dried and subsequently placed in an oven at 95° C. for 1 hour. Lastly, PMMA was removed using acetone, followed by rinsing with IPA and DI water, and dried with N2 gas. The patterning process of graphene contact is shown in FIG. 28C. First, photoresist S1813 was coated onto the graphene surface. This was followed by baking, UV exposure, and development. The exposed graphene was then etched away using reactive ion etching (RIE). Lastly, the photoresist was removed using acetone, followed by DI water rinsing and N2 drying. Devices with dimensions of 1×1 mm², 0.5×0.5 mm², and 0.3×0.3 mm² were obtained in the end with graphene electrode.

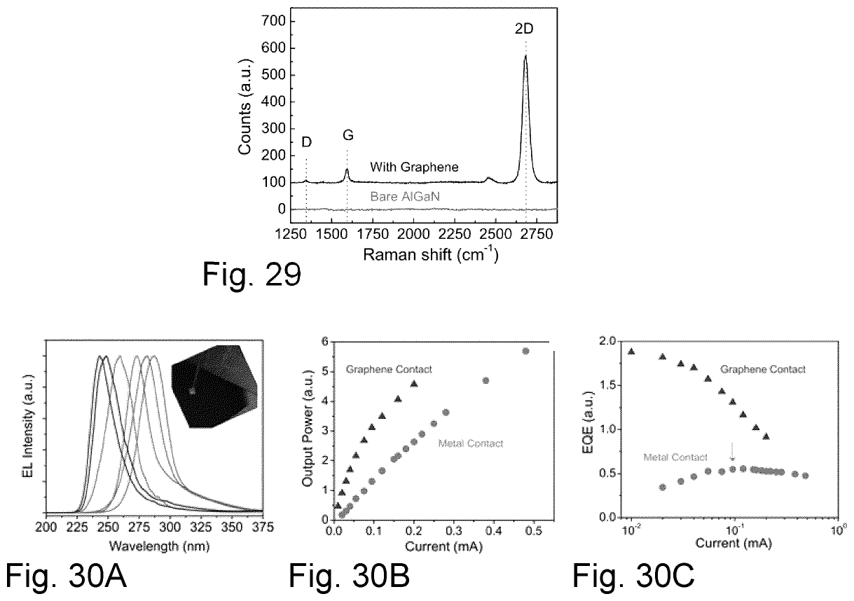

Raman spectroscopy experiments were further carried out to characterize the transferred graphene electrode. In this regard, a 532 nm green laser was used and focussed with a 50×objective onto the device top surface. The Raman spectra are shown in FIG. 29. It is seen that, compared to the bare AlGaN nanowire surface, peaks at 1343 cm⁻¹, 1590 cm⁻¹, and 2685 cm⁻¹ are measured from the region with graphene electrode, which correspond to characteristic graphene peaks D, G, 2D, respectively. The D-peak is a defect related peak and indicates impurities or disorder in the graphene. Thus, depending on the quality of the graphene, this peak might not always be present in the Raman spectra. The G-peak is due to the in-plane bond vibration of the sp2 C—C bond (1st order Raman scattering process), whereas the 2D-peak is due to a 2-phonon, 2nd order Raman scattering process. The G- and 2D-peaks are always present and are sensitive to the number of graphene layers.

In this example, the back electrode was formed by applying colloidal Ag paste to the backside of n-Si substrate. The room-temperature electroluminescence (EL) spectra for devices with different Al contents in the active region are shown in FIG. 30A. In this experiment, the electrical injection was under continuous-wave (CW) biasing by a Keithley 2400 source meter. The probe was directly in contact with the graphene electrode, as shown in the inset of FIG. 30A. The EL emission spectra were collected from the device top surface with an optical fibre, which was coupled to a deep UV spectrometer. It is seen that emission wavelength from —240 nm to 280 nm were obtained, and the emission was bright, as shown by the optical image of the light emission in the inset of FIG. 30A. This suggests that even if there is no support for graphene underneath, i.e., in the gap area amongst nanowires, graphene can still serve as the current spreading layer for the nanowire ensemble. For the present devices, similar to previous studies, blueshift of the EL emission peak and spectral narrowing were observed, which is attributed to the electrostatic screening of the electric polarization field due to the increase of carrier density.

Next, a comparison is made between the light output power for devices emitting close to 240 nm and those with graphene electrode and conventional top metal contact. In this regard, a thin metal bilayer consisting of 7-nm-thick Ti/7-nm-thick Au was deposited on the top surface, which were fabricated using standard photolithography and metallization techniques. The device size with metal contact is the same as the device size with graphene electrode. The comparison plot is shown in FIG. 30B. It is seen that the light output power of the device with graphene electrode is much higher than that with metal contact. Under an injection current of 0.2 mA, the power is improved by roughly two folds. A significantly higher EQE (defined by the ratio of the light intensity divided by the current in the present example), in particular at low injection currents, is also seen in FIG. 30C. In this example, numerous devices have been tested, and similar trends as shown in FIGS. 30B and 30C are observed. This indicates that graphene electrode can improve both the light output power and EQE of AlGaN nanowire deep UV LEDs.

However, a more severe efficiency droop is seen from devices with graphene electrode, e.g., the efficiency droop onset of devices with graphene electrode occurs at a smaller current compared to devices with metal contact, and the efficiency decrease is more rapid as well. The comparison of I-V characteristics for devices with metal contact and graphene electrode indicates that the heating effect could be the main cause for the different efficiency droop behavior.

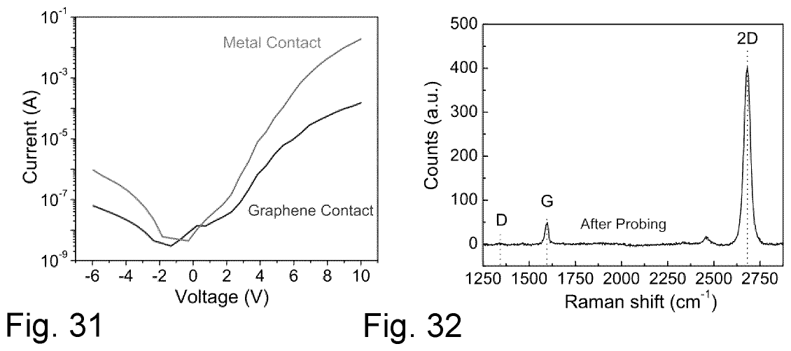

FIG. 31 shows the I-V characteristics of devices emitting around 240 nm with graphene electrode and metal contact in a semi-log scale. For both cases, the device size is 1 mm×1 mm. It is seen that the I-V characteristics of the device with graphene electrode are much worse compared to the device with metal contact. The series resistance is further estimated by using the slope close to 10 V, which yields around 430 ohm and 29k ohm for devices with metal contact and graphene electrode, respectively. Nonetheless, it is noted that the I-V characteristics of the present 240 nm emitting devices with graphene electrode are comparable to the previously demonstrated 350 nm emitting GaN-based UV LEDs with graphene electrode.

The large series resistance from devices with graphene electrode mainly can be attributed to the contact resistance, which could be due to the poor adhesion of graphene to the nanowire ensemble top surface, as the nanowire height is not uniform. Due to the large contact resistance, a more severe heating effect is expected for devices with graphene electrode compared to devices with metal contact, which could explain the earlier onset, i.e., a smaller current, of the efficiency droop for devices with graphene electrode. The large contact resistance could be a device performance limiting factor. This issue, however, could be alleviated using nanowires by selective area epitaxy.

Lastly, Raman experiments were performed on the graphene electrode after electrical injection. The Raman spectrum is shown in FIG. 32. It is seen that compared to the Raman spectrum of graphene before electrical injection, there is a negligible change of the defect related D-peak, indicating a minimal damage to the graphene. The appearance of D′-peak at 1620 cm⁻¹ is also often used as an indicator for graphene degradation due to disorder introduced into graphene. Such a peak is also absent in FIG. 32, suggesting negligible defects in the graphene after electrical injection. The degradation of graphene can also be characterized using the relative intensities of the G- and 2D-peak. A decrease in the G/2D intensity ratio indicates the degradation of the graphene due to the thinning of graphene, which is caused by an oxidation process. Comparing FIG. 29 and FIG. 32, the G/2D peak ratio is similar, again suggesting no noticeable graphene degradation in the present example. A degradation, however, could be seen at higher injection currents, which is not the focus of the present example.

In conclusion, this example provides a detailed study of applying graphene to AlGaN nanowire deep UV LEDs, and devices emitting down to around 240 nm are demonstrated. Comparing to devices with metal contact, the light output power and relative EQE of devices with graphene electrode are increased significantly at low injection currents. Nonetheless, a more severe efficiency droop is seen from devices with graphene electrode as the injection current increases, presumably due to the heating effect from the large contact resistance. Poor adhesion might be the main cause for the large contact resistance; this issue could be mitigated by using nanowires with selective area epitaxy wherein the nanowire height can be controlled precisely. The optical polarization change in AlGaN alloys from TE to TM makes it difficult to obtain surface deep UV emission at short wavelengths, and nanowires have been found to be able to mitigate this issue, in addition to the advantage of vertical current injection scheme. Nonetheless, the deep UV light blocking by metal contact is a limitation. This study shows that graphene can help to improve the device optical performance for such nanowire devices. As Si is a decent reflector at short UV wavelengths, AlGaN nanowires by selective area epitaxy on Si, with graphene electrode on top, could be a viable path for surface-emitting vertical semiconductor deep UV LEDs at short wavelengths

As can be understood, the examples described above and illustrated are intended to be exemplary only. The scope is indicated by the appended claims.

1. A substrate for a semiconductor device, the substrate comprising:
a semiconductor wafer;
an intermediate nanowire layer having a plurality of nanowires each having in succession a base portion mounted to the semiconductor wafer, an elongated body portion extending away from the semiconductor wafer, and a tip portion; and
a buffer layer of aluminum nitride being made integral to the tip portions of the plurality of nanowires.

2. The substrate of claim 1 wherein the buffer layer of aluminum nitride has a thickness ranging between about 20 nm and about 2 μm.

3. The substrate of claim 1 wherein the buffer layer of aluminum nitride is at least one of metal-polar and non-metal polar.

4. The substrate of claim 3 wherein the buffer layer of aluminum nitride is at least one of nitrogen-polar and aluminum-polar.

5. The substrate of claim 1 further comprising an epilayer of a semiconductor material deposited on the buffer layer of aluminum nitride.

6. The substrate of claim 5 wherein the epilayer is at least one of nitrogen-polar and aluminum-polar.

7. The substrate of claim 5 wherein the semiconductor material of the epilayer is a group-III nitride semiconductor.

8. The substrate of claim 5 wherein the semiconductor material is aluminum gallium nitride.

9. The substrate of claim 8 wherein the aluminum gallium nitride has an aluminum content varying between ˜35% and ˜70%.

10. The substrate of claim 1 wherein the semiconductor wafer is a silicon wafer.

11. The substrate of claim 1 wherein the nanowires are made of gallium nitride.

12. The substrate of claim 1 wherein the nanowires are grown in a self-organized manner with respect to the semiconductor wafer.

13. The substrate of claim 1 wherein said buffer layer has a plurality of coalescence boundaries running within the buffer layer and terminating short of a distal face of the buffer layer.

14. The substrate of claim 1 wherein said nanowires have a cross-sectional area increasing from the semiconductor wafer to the buffer layer.

15. The substrate of claim 1 further comprising a base layer of aluminum nitride atop the semiconductor wafer, the intermediate nanowire layer being mounted to the base layer of aluminum nitride.

16. The substrate of claim 15 wherein the base layer has a thickness ranging between about 0.5 nm and 10 nm.

17. The substrate of claim 1 further comprising a graphene electrode mounted to the buffer layer of aluminum nitride.

18. A method of manufacturing a substrate for a semiconductor device, the method comprising:
growing a plurality of nanowires on a semiconductor wafer, the nanowires having in succession a base portion mounted to the semiconductor wafer, an elongated body portion extending away from the semiconductor wafer, and a tip portion; and
making a buffer layer of aluminum nitride integral to the tip portions of the plurality of nanowires.

19. The method of claim 18 wherein said making is performed under environmental conditions slowing aluminum adatom migration within the buffer layer, said making including making the buffer layer with a non-metal surface termination.

20-42. (canceled)

43. A substrate for a semiconductor device, the substrate comprising:
a semiconductor wafer;
an intermediate nanowire layer having a plurality of nanowires each having in succession a base portion mounted to the semiconductor wafer, an elongated body portion extending away from the semiconductor wafer, and a tip portion; and
a graphene electrode being made integral to the tip portions of the plurality of nanowires.
